(19) United States
(12) Patent Application Publication
(10) Pub. No.: US 2026/0190578 A1
(43) Pub. Date: Jul. 2, 2026

(54) DISPLAY PANEL AND ELECTRONIC DEVICE INCLUDING THE SAME

(71) Applicant: Samsung Display Co., Ltd., Yongin-si (KR)

(72) Inventors: Mankyu Jo, Yongin-si (KR); Jonghwa Park, Yongin-si (KR); Kyungho Kim, Yongin-si (KR)

(21) Appl. No.: 19/402,061

(22) Filed: Nov. 26, 2025

(30) Foreign Application Priority Data
Dec. 27, 2024 (KR) 10-2024-0199347

(51) Int. Cl. H10H 29/49; G09G 3/3233; H10H 29/32

(52) U.S. Cl. CPC H10H 29/49; H10H 29/32; G09G 3/3233; G09G 2300/0819; G09G 2300/0852; G09G 2300/0861; G09G 2320/0233; G09G 2320/0238

(57) ABSTRACT

A display panel includes: a base layer including a display area, and a non-display area surrounding around the display area; a first pixel circuit layer in the display area, and including a transistor and insulating layers; a second pixel circuit layer in the display area, and including a transistor and insulating layers; a first light-emitting diode on the first pixel circuit layer, and electrically connected to the transistor of the first pixel circuit layer; a second light-emitting diode on the second pixel circuit layer, and electrically connected to the transistor of the second pixel circuit layer; and a connection line electrically connecting the transistor of the first pixel circuit layer to the transistor of the second pixel circuit layer, and including a first connection line, and a second connection line having a lower resistance variation rate according to an elongation rate than that of the first connection line.

### CROSS-REFERENCE TO RELATED APPLICATION

The present application claims priority to and the benefit of Korean Patent Application No. 10-2024-0199347, filed on Dec. 27, 2024, in the Korean Intellectual Property Office, the entire disclosure of which is incorporated by reference herein.

### BACKGROUND

### 1. Field

Aspects of embodiments of the present disclosure relate to a display panel, and an electronic device including the display panel.

### 2. Description of the Related Art

Generally, with the development of display panels for visually displaying electrical signals, various display panels having excellent characteristics, such as a smaller thickness, a smaller weight, reduced power consumption, and/or the like, and electronic devices including the display panels, have been introduced. For example, display panels having various suitable structures, such as flexible display panels that are foldable or rollable, stretchable display panels, and the like, and electronic devices including the display panels, have been actively researched and developed.

### SUMMARY

Embodiments of the present disclosure may be directed to a display panel for realizing a high-quality image, even when extended, and an electronic device including the display panel. However, the present disclosure is not limited to the above aspects and features. Additional aspects and features will be set forth, in part, in the description that follows, and in part, may be apparent from the description, or may be learned by practicing one or more of the presented embodiments of the present disclosure.

According to one or more embodiments of the present disclosure, a display panel includes: a base layer including a display area, and a non-display area surrounding around the display area; a first pixel circuit layer in the display area of the base layer, and including a transistor and insulating layers; a second pixel circuit layer in the display area of the base layer, and including a transistor and insulating layers; a first light-emitting diode on the first pixel circuit layer, and electrically connected to the transistor of the first pixel circuit layer; a second light-emitting diode on the second pixel circuit layer, and electrically connected to the transistor of the second pixel circuit layer; and a connection line electrically connecting the transistor of the first pixel circuit layer to the transistor of the second pixel circuit layer. The connection line includes a first connection line and a second connection line that are stacked, the second connection line having a lower resistance variation rate according to an elongation rate than that of the first connection line.

In an embodiment, an initial resistance of the second connection line in an undeformed state may be greater than an initial resistance of the first connection line in the undeformed state.

In an embodiment, the display panel may further include: a first line electrically connected to the transistor of the first pixel circuit layer; and a second line electrically connected to the transistor of the second pixel circuit layer. The connection line may electrically connect the first line to the second line, and the first connection line may be in direct contact with the first line and the second line.

In an embodiment, the second connection line may cover at least some of side surfaces of the first connection line.

In an embodiment, an interface in contact with the second connection line from among side surfaces of the first connection line may include a plurality of protrusions protruding toward the second connection line.

In an embodiment, the base layer may include a recess portion on an upper surface facing toward the first pixel circuit layer and the second pixel circuit layer, the connection line may be located in the recess portion, the first connection line may be on the second connection line, the second connection line may cover a lower surface and side surfaces of the first connection line, and the second connection line may be in contact with the base layer.

In an embodiment, the connection line may be on an upper surface of the base layer facing toward the first pixel circuit layer and the second pixel circuit layer, the second connection line may be on the first connection line, the display panel may further include a protective layer covering the first light-emitting diode and the second light-emitting diode, and the second connection line may be in contact with the protective layer.

In an embodiment, the connection line may include: a first edge portion adjacent to the first pixel circuit layer; a second edge portion adjacent to the second pixel circuit layer; and a central portion between the first edge portion and the second edge portion.

In an embodiment, based on a thickness direction of the base layer, each of a thickness of the first edge portion of the second connection line and a thickness of the second edge portion of the second connection line may be greater than a thickness of the central portion of the second connection line.

In an embodiment, based on the thickness direction of the base layer, each of the thickness of the first edge portion of the second connection line and the thickness of the second edge portion of the second connection line may satisfy

$$\frac{{ρ}_{2}}{{ρ}_{1}} {t}_{1} \leq {t}_{21} \leq 3 {t}_{1} ,$$

where t₂₁ may be the thickness of the first edge portion or the second edge portion of the second connection line, t₁ may be a thickness of the first connection line, ρ₁ may be a specific resistance of the first connection line, and ρ₂ may be a specific resistance of the second connection line.

In an embodiment, based on the thickness direction of the base layer, the thickness of the central portion of the second connection line may satisfy

$$0 < {t}_{22} < \frac{{ρ}_{2}}{{ρ}_{1}} {t}_{1} ,$$

where t₂₂ may be the thickness of the central portion of the second connection line, t₁ may be a thickness of the first connection line, ρ₁ may be a specific resistance of the first connection line, and ρ₂ may be a specific resistance of the second connection line.

In an embodiment, in a plan view, the first edge portion, the central portion, and the second edge portion may be sequentially located along a first direction, and based on a second direction crossing the first direction, each of a width of the first edge portion of the second connection line and a width of the second edge portion of the second connection line may be greater than a width of the central portion of the second connection line.

In an embodiment, in the plan view, each of the width of the first edge portion of the second connection line in the second direction and the width of the second edge portion of the second connection line in the second direction may satisfy w₁≤w₂₁≤w₁+20 μm, where w₁ may be a width of the first connection line, and w₂₁ may be the width of the first edge portion or the second edge portion of the second connection line.

In an embodiment, in the plan view, the width of the central portion of the second connection line in the second direction may satisfy 0≤w₂₂≤w₁−30 μm, where w₁ may be a width of the first connection line, and w₂₂ may be the width of the central portion of the second connection line.

In an embodiment, the connection line may further include an adhesion layer between the first connection line and the second connection line, and an interface in contact with the adhesion layer from among side surfaces of the first connection line may include a plurality of protrusions protruding toward the adhesion layer.

In an embodiment, the connection line may further include a third connection line including a same material as that of the second connection line, the second connection line may cover a lower surface and side surfaces of the first connection line, the third connection line may cover an upper surface of the first connection line, and the second connection line and the third connection line may surround around the first connection line.

In an embodiment, the display panel may further include: a strain sensor in the non-display area of the base layer; and a sensor line configured to transmit an electrical signal of the strain sensor. The strain sensor may include a sensing portion, and a connection portion connecting the sensing portion to the sensor line.

In an embodiment, the sensing portion may be on a same layer as that of the first connection line, and may include a same material as that of the first connection line.

In an embodiment, each of the connection portion and the sensor line may include: a first layer on a same layer as that of the first connection line, and including a same material as that of the first connection line; and a second layer on a same layer as that of the second connection line, and including a same material as that of the second connection line.

According to one or more embodiments of the present disclosure, an electronic device includes: a display panel; and a lower cover defining an exterior shape and having an opening in a front surface thereof, the opening exposing a portion of the display panel. The display panel includes: a base layer including a display area, and a non-display area surrounding around the display area; a first pixel circuit layer in the display area of the base layer, and including a transistor and insulating layers; a second pixel circuit layer in the display area of the base layer, and including a transistor and insulating layers; a first light-emitting diode on the first pixel circuit layer, and electrically connected to the transistor of the first pixel circuit layer; a second light-emitting diode on the second pixel circuit layer, and electrically connected to the transistor of the second pixel circuit layer; and a connection line electrically connecting the transistor of the first pixel circuit layer to the transistor of the second pixel circuit layer. The connection line includes a first connection line and a second connection line that are stacked, the second connection having a lower resistance variation rate according to an elongation rate than that of the first connection line.

According to some embodiments of the present disclosure, a display panel having an improved flexibility and realizing an improved image quality (e.g., an excellent quality image), and an electronic device including the display panel, may be provided.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1A is a schematic perspective view of an electronic device according to an embodiment of the present disclosure.

FIG. 1B is a schematic block diagram of an electronic device according to an embodiment of the present disclosure.

FIG. 2 is a schematic perspective view of a display panel according to an embodiment of the present disclosure.

FIGS. 3A and 3B are perspective views of the display panel of FIG. 2 that is stretched in a first direction.

FIG. 3C is a perspective view of the display panel of FIG. 2 that is stretched in a second direction.

FIG. 3D is a perspective view of the display panel of FIG. 2 that is stretched in the first direction and the second direction.

FIG. 3E is a perspective view of the display panel of FIG. 2 that is stretched in a third direction.

FIG. 4 is a schematic plan view of a display panel according to an embodiment of the present disclosure.

FIG. 5 is a schematic plan view of an arrangement of pixels of a display panel according to an embodiment of the present disclosure.

FIG. 6 is a schematic cross-sectional view of a portion of a display panel according to an embodiment of the present disclosure.

FIGS. 7A-7C are each an equivalent circuit diagram of a pixel of a display panel according to some embodiments of the present disclosure.

FIGS. 8A and 8B are each a schematic cross-sectional view of a light-emitting diode of a display panel according to some embodiments of the present disclosure.

FIG. 9 is a schematic plan view of a portion of a display panel according to an embodiment of the present disclosure.

FIG. 10 is a schematic cross-sectional view of a portion of a display panel taken along the line I-I′ of FIG. 9 according to an embodiment of the present disclosure.

FIG. 11 is a schematic cross-sectional view of a portion of a display panel taken along the line II-II′ of FIG. 9 according to an embodiment of the present disclosure.

FIG. 12 is a schematic plan view of a portion of a display panel according to an embodiment of the present disclosure.

FIG. 13 is a schematic cross-sectional view of a portion of a display panel according to an embodiment of the present disclosure.

FIG. 14 is a schematic cross-sectional view of a portion of a display panel according to an embodiment of the present disclosure.

FIG. 15 is a schematic plan view of a portion of a display panel according to an embodiment of the present disclosure.

FIG. 16 is a schematic cross-sectional view of a portion of a display panel according to an embodiment of the present disclosure.

FIG. 17 is a schematic cross-sectional view of a portion of a display panel according to an embodiment of the present disclosure.

FIG. 18 is a schematic plan view of a display panel according to an embodiment of the present disclosure.

FIG. 19 is a schematic cross-sectional view of a portion of a display panel according to an embodiment of the present disclosure.

FIGS. 20A-20G are schematic perspective views of some examples of an electronic device including a display panel according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

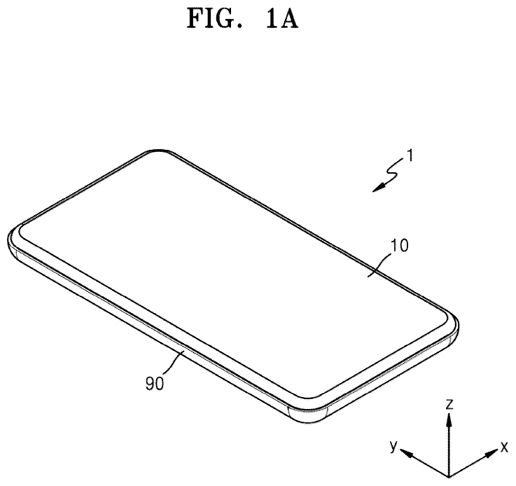

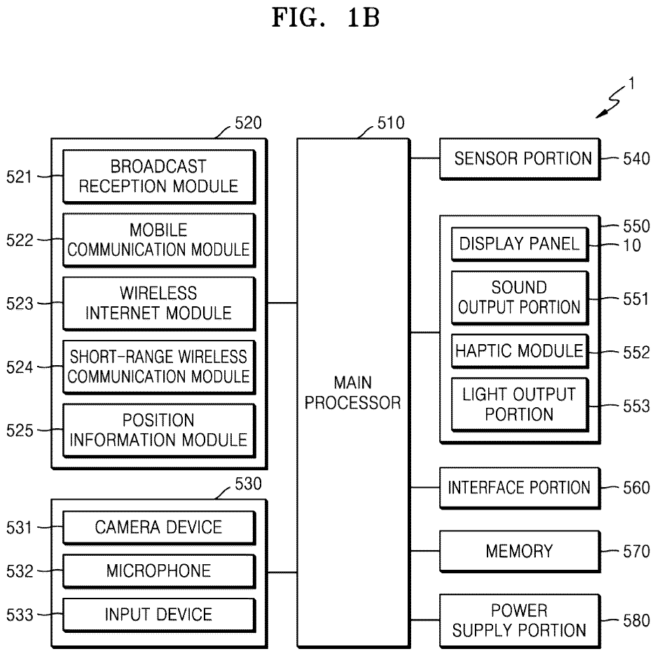

FIG. 1A is a schematic perspective view of an electronic device 1 according to an embodiment of the present disclosure. FIG. 1B is a schematic block diagram of the electronic device 1 according to an embodiment of the present disclosure.

Referring to FIGS. 1A and 1B, the electronic device 1 may include a display panel 10 according to an embodiment of the present disclosure, and may be a device for displaying a video or a static image. The electronic device 1 may be used as a display screen for not only portable electronic devices, such as a mobile phone, a smartphone, a tablet personal computer (PC), a mobile communication terminal, an electronic notebook, an electronic book, a portable multimedia player (PMP), a navigation device, a ultra mobile PC (UMPC), and/or the like, but also a display screen for various suitable products, such as a television, a laptop computer, a monitor, an advertisement board, an Internet of things (IOT) device, and/or the like. The electronic device 1 according to an embodiment may be used for wearable devices, such as a smart watch, a watch phone, a glasses-type display, and a head-mounted display (HMD). The electronic device 1 according to an embodiment may be used as a gauge of a vehicle, a center information display (CID) on a center fascia or a dashboard of a vehicle, a room mirror display substituting a side-view mirror of a vehicle, or a display arranged on a rear surface of a front seat as an entertainment device for a backseat of a vehicle.

FIG. 1A illustrates that the electronic device 1 according to an embodiment is used as a smartphone. The electronic device 1 may include the display panel 10, and a lower cover 90 arranged below (e.g., under) the display panel 10. The electronic device 1 may include a cover window covering an upper surface of the display panel 10.

The lower cover 90 may form the exterior of the electronic device 10, and may have, in a front surface thereof, an opening exposing a portion of the display panel 10. The lower cover 90 may be shaped to have a surface corresponding to the display panel 10 that is open, and may be assembled with the display panel 10. The lower cover 90 may form the exterior of a lower surface of the electronic device 1, and between the display panel 10 and the lower cover 90, a display circuit board, a component, a main circuit board, a battery, a driver, and/or the like may be arranged. The lower cover 90 may include a plastic, a metal, or both a plastic and a metal.

The electronic device 1 may include a main processor 510, a wireless communicator 520, an input portion 530, a sensor portion 540, an output portion 550, an interface portion 560, a memory 570, and/or a power supply portion 580.

The main processor 510 may control all the functions of the electronic device 1. For example, the main processor 510 may output digital video data to a data driver through the display circuit board, so that the display panel 10 may display an image. The main processor 510 may receive sensing data from a touch sensor driver. The main processor 510 may determine whether or not there is a user's touch, according to the sensing data, and may perform an operation according to a direct touch or a proximity touch of a user. The main processor 510 may include an application processor, a central processing unit, or a system chip including an integrated circuit (IC).

The camera device 531 may process an image frame, such as a static image or a motion image, obtained in a camera mode through an image sensor, and may output the processed image frame to the main processor 510. The camera device 531 may include at least one of a camera sensor (e.g., a charge-coupled device (CCD) sensor, a complementary metal-oxide semiconductor (CMOS) sensor, and/or the like), a photo sensor (e.g., an image sensor), and/or a laser sensor. The camera device 531 may be connected to the image sensor, and may process an image input through the image sensor.

The wireless communicator 520 may include at least one of a broadcasting reception module 521, a mobile communication module 522, a wireless Internet module 523, a short-range wireless communication module 524, and/or a position information module 525.

The broadcasting reception module 521 may receive, from an external broadcasting management server, a broadcasting signal and/or broadcasting-related information, through a broadcasting channel. The broadcasting channel may include a satellite channel and a ground wave channel.

The mobile communication module 522 may transmit and receive a wireless signal to and from at least one of a base station, an external terminal, and/or a server on mobile communication networks established according to the technical standards for mobile communication or the communication methods (e.g., a global system for mobile communication (GSM), code division multiple access (CDMA), CDMA 2000, enhanced voice-data optimized or enhanced voice-data only (EV-DO), wideband CDMA (WCDMA), high speed downlink packet access (HSDPA), high speed uplink packet access (HSUPA), long term evolution (LTE), LTE-advanced (LTE-A), and/or the like). The wireless signal may include a sound call signal, a video telephony call signal, or various suitable forms of data according to transmissions and receptions of text/multimedia messages.

The wireless Internet module 523 may provide wireless Internet access. The wireless Internet module 523 may transmit and receive a wireless signal on a communication network according to wireless Internet techniques. The wireless Internet techniques may include, for example, a wireless local area network (WLAN), wireless-fidelity (Wi-Fi), Wi-Fi direct, a digital living network alliance (DLNA), and/or the like.

The short-range wireless communication module 524 may be used for short-range communications, and may support short-range communications by using at least one of Bluetooth™, radio frequency identification (RFID), infrared data association (IrDA), an ultra wideband (UWB), Zigbee, near-field communication (NFC), Wi-Fi, Wi-Fi direct, and/or a wireless universal serial bus (USB). The short-range wireless communication module 524 may support wireless communications between the electronic device 1 and a wireless communication system, between the electronic device 1 and another electronic device, or between the electronic device 1 and a network on which another electronic device (e.g., an external server) is located, through a short-range wireless communication network. The short-range wireless communication network may include wireless personal area networks. The other electronic device may include a wearable device, which may exchange data (e.g., which may be synchronized) with the electronic device 1.

The position information module 525 may obtain a position (e.g., a current position) of the electronic device 1, and may include a global positioning system (GPS) module or a Wi-Fi module.

The input portion 530 may include an image input portion, such as the camera device 531 to input an image signal, a sound input portion, such as a microphone 532 to input a sound signal, and an input device 533 to receive information from a user.

The camera device 531 may process an image frame, such as a static image or a motion image, obtained through the image sensor in a video call mode or a photographing mode. The processed image frame may be displayed on the display panel 10 or stored in the memory 570.

The microphone 532 may process an external sound signal into electrical sound data. The processed sound data may be variously used according to a function performed (e.g., an application executed) by the electronic device 1.

The main processor 510 may control the operations of the electronic device 1 according to information input through the input device 533. The input device 533 may include a mechanical input device, such as a button, a dome switch, a jog wheel, a jog switch, and/or the like, on a rear surface or a side surface of the electronic device 1, or a touch input device. The touch input device may be formed as a touch screen layer of the display panel 10.

The sensor portion 540 may include one or more sensors to sense at least one of information in the electronic device 1, information of an ambient environment surrounding the electronic device 1, and/or user information, and may generate a sensing signal according to the sensed information. Based on the sensing signal, the main processor 510 may drive the electronic device 1, control operations of the electronic device 1, or process data and perform functions or operations related to an application installed on the electronic device 1. The sensor portion 540 may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environmental sensor (e.g., a barometer, a hygrometer, a thermometer, a radioactivity sensor, a heat sensing sensor, a gas sensing sensor, and/or the like), and/or a chemical sensor (e.g., an electronic nose, a healthcare sensor, a biometric sensor, and/or the like).

The output portion 550 may generate an output related to a visual sense, an auditory sense, a haptic sense, or the like, and may include at least one of the display panel 10, a sound output portion 551, a haptic module 552, and/or a light output portion 553.

The display panel 10 may display (e.g., may output) information processed by the electronic device 1. For example, the display panel 10 may display execution screen information of an application driven by the electronic device 1, or may display user interface (UI) or graphics UI (GUI) information according to the execution screen information. The display panel 10 may include a display layer for displaying an image, and a touch screen layer to sense a touch input of a user. Thus, while the display panel 10 may function as an example of the input device 533 to provide an input interface between the electronic device 1 and a user, the display panel 10 may function as an example of the output portion 550 to provide an output interface between the electronic device 1 and the user.

The sound output portion 551 may output sound data received from the wireless communicator 520 or stored in the memory 570 in a signal reception mode, a call mode, a recording mode, a voice recognition mode, a broadcasting reception mode, and/or the like. The sound output portion 551 may output a sound signal related to a function (e.g., a call signal reception sound, a message reception sound, and/or the like) performed by the electronic device 1. The sound output portion 551 may include a receiver and a speaker. At least one of the receiver and/or the speaker may include a sound generation device, which is attached below (e.g., under) the display panel 10 and vibrates the display panel 10, to output sound. The sound generation device may include a piezoelectric element or a piezoelectric actuator contracting or expanding according to an electrical signal, or an exciter vibrating the display panel 10 by generating a magnetic force by using a voice coil.

The haptic module 552 may generate various haptic effects, which may be felt by a user. The haptic module 552 may provide a vibration to the user as a haptic effect. The haptic module 552 may transmit the haptic effects through a direct contact. Also, the haptic module may allow a user to feel the haptic effects through a sensation of muscles, such as a finger, an arm, and/or the like.

The light output portion 553 may use light of a light source to output a signal for notifying an occurrence of an event. Examples of the event occurring in the electronic device 1 may include a message reception, a call signal reception, an absent call, an alarm, a schedule notification, an email reception, information reception through an application, and/or the like. The signal output by the light output portion 553 may be realized via an emission of light of a single color or a plurality of colors on a front surface or a rear surface of the electronic device 1. The outputting of the signal may be ended via a sensing of the electronic device 1 with respect to a user's identification of an event.

The interface portion 560 may serve as a path between the electronic device 1 and various suitable kinds of external devices connected to the electronic device 1. The interface portion 560 may include at least one of a wired/wireless headset port, an external charger port, a wired/wireless data port, a memory card port, a port connecting a device including an identification module, an audio input/output (I/O) port, a video I/O port, and/or an earphone port. When an external device is connected to the interface portion 560, the electronic device 1 may perform an appropriate control operation related to the external device connected to the interface portion 560.

The memory 570 may store data for supporting various functions of the electronic device 1. The memory 570 may store a plurality of applications driven in the electronic device 1, and data and instructions for operations of the electronic device 1. At least some of the plurality of applications may be downloaded from an external server through a wireless communication. The memory 570 may store an application for an operation of the main processor 510, and may temporarily store input/output data, for example, such as data for a phone book, a message, a static image, a motion image, and/or the like. Also, the memory 570 may store haptic data for a vibration of various patterns provided to the haptic module 552, and sound data related to various sounds provided to the sound output portion 551. The memory 570 may include a storage medium of at least one kind from among a flash memory kind, a hard disk kind, a solid state disk (SSD) kind, a silicon disk driver (SDD) kind, a multimedia card micro kind, a card memory kind (e.g., a secure digital (SD) memory, an extreme digital (XD) memory, and/or the like) random-access memory (RAM), static RAM (SRAM), read-only memory (ROM), electrically erasable programmable ROM (EEPROM), programmable ROM (PROM), a magnetic memory, a magnetic disk, and/or an optical disk.

The power supply portion 580 may supply power to each component included in the electronic device 1 by receiving external power and internal power under control by the main processor 510. The power supply portion 580 may include a battery. Also, the power supply portion 580 may include a connection port, and the connection port may be provided as an example of the interface portion 560 to which an external charger for supplying power for charging the battery is electrically connected. As another example, the power supply portion 580 may charge the battery by using a wireless method, without using the connection port.

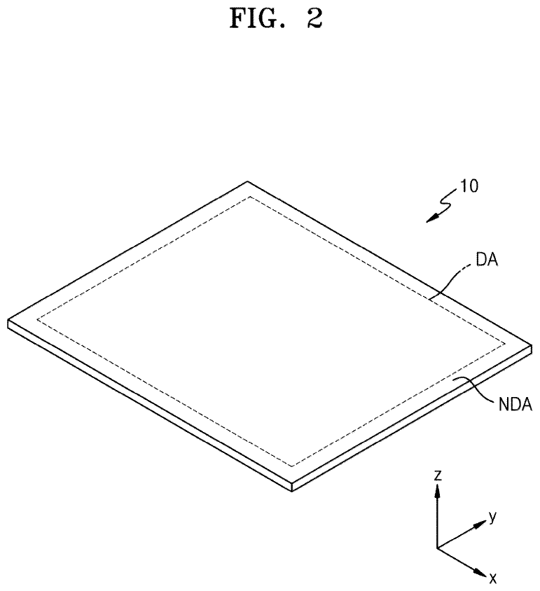

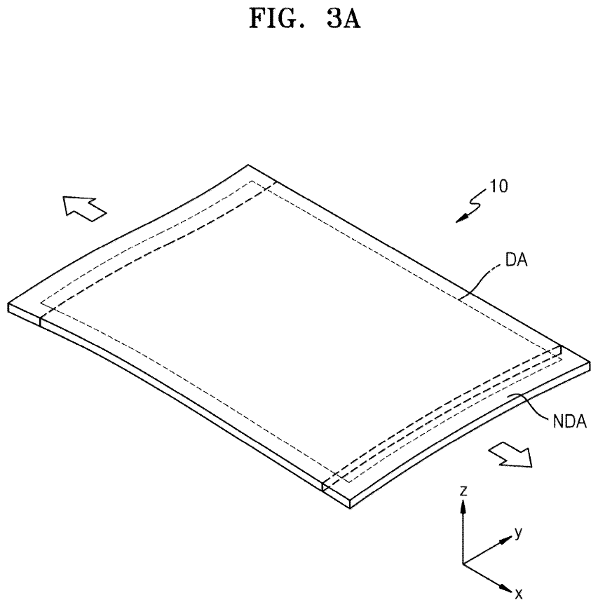

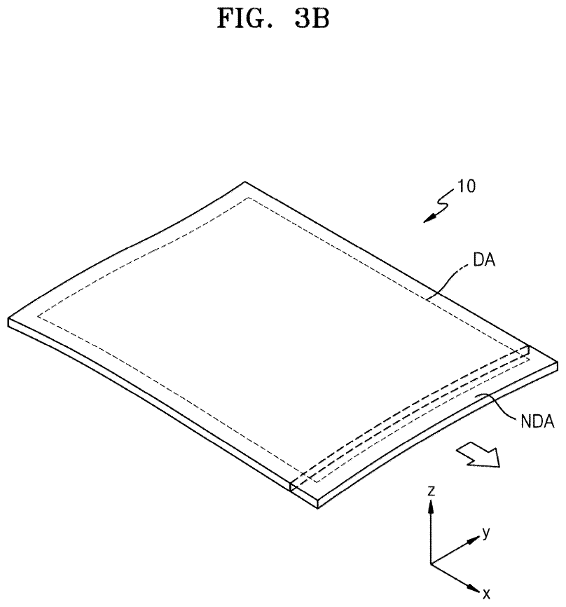

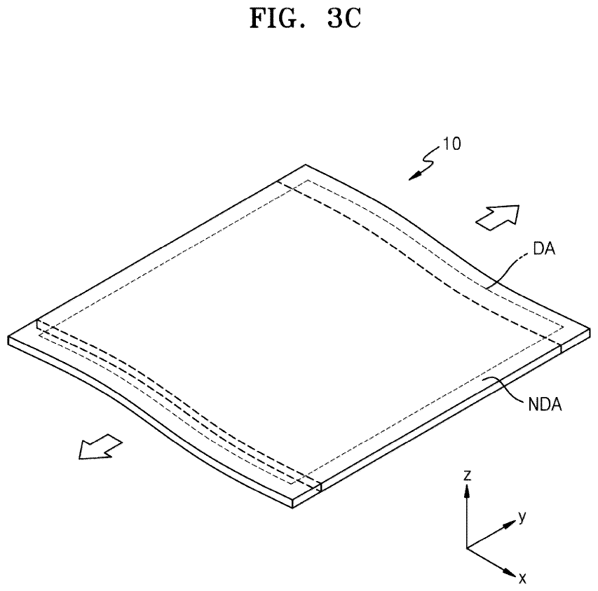

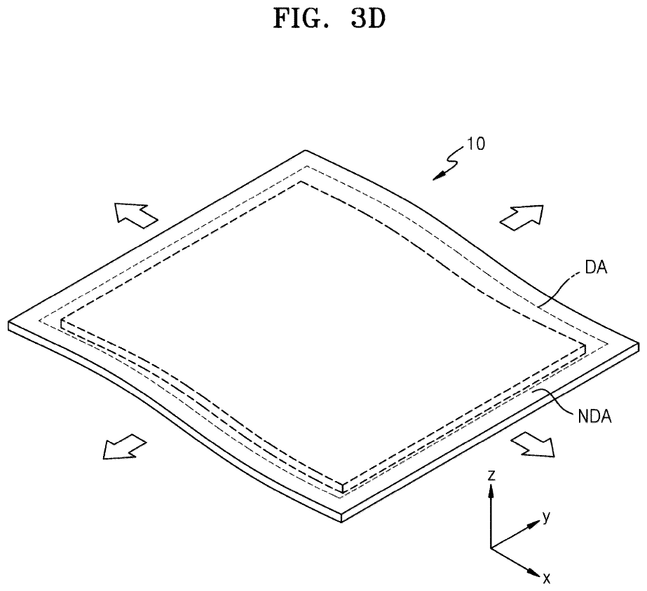

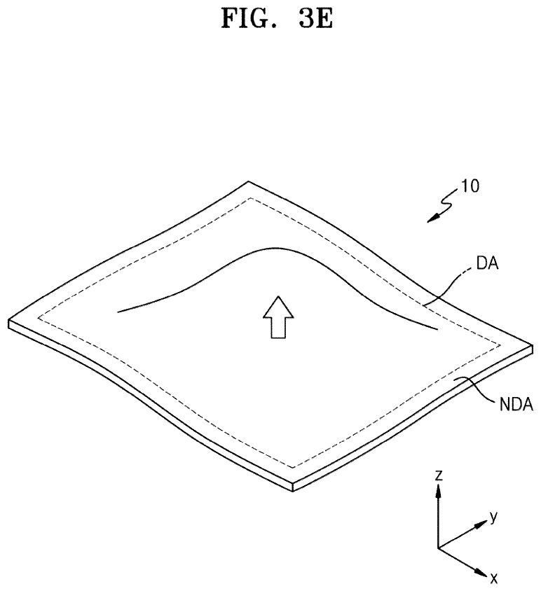

FIG. 2 is a schematic perspective view of the display panel 10 according to an embodiment of the present disclosure. FIGS. 3A and 3B are perspective views of the display panel 10 of FIG. 2 that is stretched in a first direction. FIG. 3C is a perspective view of the display panel 10 of FIG. 2 that is stretched in a second direction. FIG. 3D is a perspective view of the display panel 10 of FIG. 2 that is stretched in the first direction and the second direction. FIG. 3E is a perspective view of the display panel 10 of FIG. 2 that is stretched in a third direction.

Referring to FIG. 2, the display panel 10 may include a display area DA and a non-display area NDA. The display area DA may include a plurality of pixels. The display panel 10 may provide an image (e.g., a certain or predetermined image) by using light emitted from the plurality of pixels. The non-display area NDA may be arranged outside the display area DA. The non-display area NDA may entirely surround (e.g., around a periphery of) the display area DA.

The display panel 10 may be stretched or compressed in various suitable directions. The display panel 10 may be stretched in a first direction (e.g., the x direction and/or the −x direction) by an external force applied by an external object or a user. According to an embodiment, as illustrated in FIGS. 3A and 3B, the display area DA and/or the non-display area NDA of the display panel 10 may be stretched in the first direction (e.g., the x direction and/or the −x direction). For example, as illustrated in FIG. 3A, the display area DA and/or the non-display area NDA of the display panel 10 may be stretched in the x direction and the −x direction, or as illustrated in FIG. 3B, the display area DA and/or the non-display area NDA of the display panel 10 may be stretched in the x direction with one side of the display panel 10 being fixed.

The display panel 10 may be stretched in a second direction (e.g., the y direction and/or the −y direction) by an external force applied by an external object or a user. According to an embodiment, as illustrated in FIG. 3C, the display area DA and/or the non-display area NDA of the display panel 10 may be stretched in the y direction and the −y direction. According to another embodiment, the display area DA and/or the non-display area NDA of the display panel 10 may be stretched in one of the y direction or the −y direction with one side of the display panel 10 being fixed.

The display panel 10 may be stretched in a plurality of directions, for example, such as in the first direction (e.g., the x direction and/or the −x direction) and the second direction (e.g., the y direction and/or the −y direction), by an external force applied by an external object or a part of a human body. As illustrated in FIG. 3D, the display area DA and/or the non-display area NDA of the display panel 10 may be stretched in the ±x directions and the ±y directions.

The display panel 10 may be stretched in a third direction (e.g., the z direction or the −z direction) by an external force applied by an external object or a part of a human body. According to an embodiment, FIG. 3E illustrates that a portion of the display panel 10, for example, such as a region of the display area DA, may protrude in the z direction. According to another embodiment, a portion of the display panel 10, for example, such as a region of the display area DA, may protrude in the −z direction (e.g., may be recessed in the −z direction).

FIGS. 3A to 3E illustrate that the display apparatus 1 may be stretched in the first direction, the second direction, and/or the third direction. However, the present disclosure is not limited thereto. According to another embodiment, the display panel 10 may be variously deformed to have various amorphous shapes, such as a shape that is bent or twisted with respect to two or more axes and/or the like.

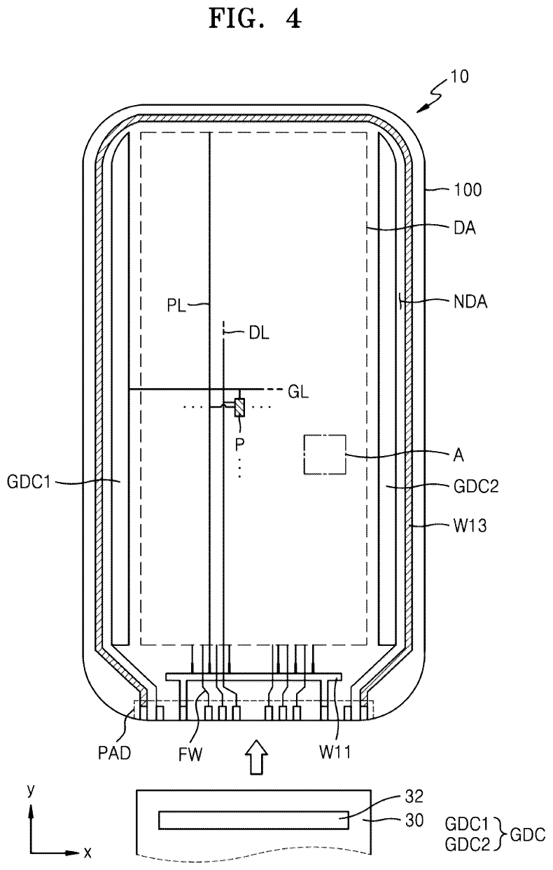

FIG. 4 is a schematic plan view of the display panel 10 according to an embodiment of the present disclosure.

Referring to FIG. 4, the display panel 10 may include the display area DA, and the non-display area NDA surrounding (e.g., around a periphery of) the display area DA. Pixels P may be arranged in the display area DA of a substrate 100. Each of the pixels P may display an image by using light emitted from a light-emitting element, such as a light-emitting diode. Each light-emitting diode may emit, for example, red, green, or blue light.

Each light-emitting diode may be electrically connected to a pixel circuit, and each pixel circuit may include transistors and a storage capacitor. Each of the pixel circuits may be electrically connected to peripheral circuits and peripheral lines arranged in the non-display area NDA. The peripheral circuits arranged in the non-display area NDA may include a gate driving circuit GDC and a terminal portion PAD. The peripheral lines may include a driving voltage supply line W11, a common voltage supply line W13, and a fanout line FW.

The gate driving circuit GDC may include drivers to provide an electrical signal to gate electrodes respectively included in the transistors that are electrically connected to the light-emitting elements. In more detail, the gate driving circuit GDC may apply, through gate lines GL, a scan signal to each of the pixel circuits corresponding to the pixels P.

The gate driving circuit GDC may include a first gate driving circuit GDC1 and a second gate driving circuit GDC2 arranged at both sides (e.g., opposite sides) with the display area DA therebetween. The second gate driving circuit GDC2 may be arranged on an opposite side to the first gate driving circuit GDC1 with respect to the display area DA, and may be approximately in parallel with the first gate driving circuit GDC1. Some of the pixel circuits may be electrically connected to the first gate driving circuit GDC1, and the others of the pixel circuits may be electrically connected to the second gate driving circuit GDC2. According to some embodiments, the second gate driving circuit GDC2 may be omitted as needed or desired.

The terminal portion PAD may be arranged at a side of the substrate 100. The pad portion PAD may not be covered by an insulating layer, and may be exposed so as to be connected to a display circuit board 30. A display driver 32 may be arranged on the display circuit board 30. The display driver 32 may generate a control signal that is transmitted to the first gate driving circuit GDC1 and the second gate driving circuit GDC2. The display driver 32 may generate a data signal, and the generated data signal may be transmitted to the pixel circuits of the pixels P through the fanout lines FW and data lines DL connected to the fanout lines FW.

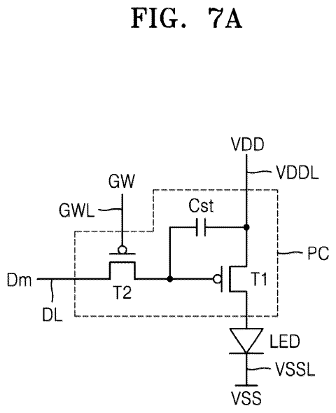

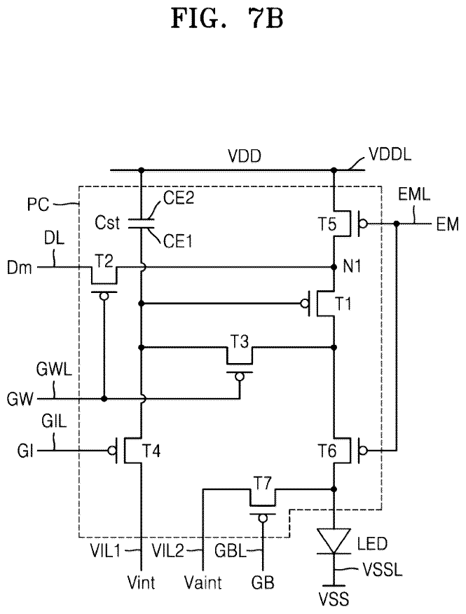

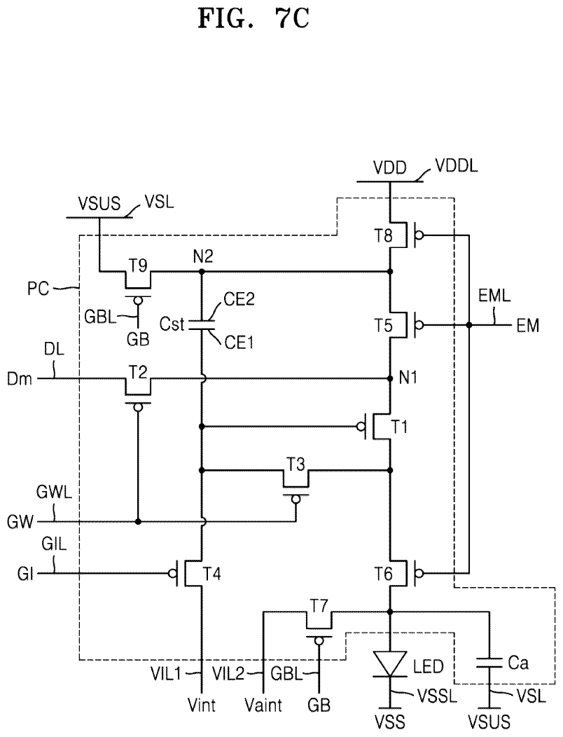

The display driver 32 may supply a first power voltage VDD (e.g., see FIG. 7A) to the driving voltage supply line W11, and a second power voltage VSS to the common voltage supply line W13. The first power voltage VDD (e.g., see FIG. 7A) may be applied to the pixel circuit of the pixel P through a driving voltage line PL connected to the driving voltage supply line W11, and the second power voltage VSS may be applied to an opposite electrode of the light-emitting element by being connected to the common voltage supply line W13. The driving voltage supply line W11 may extend in the x direction below (e.g., under) the display area DA. The common voltage supply line W13 may have a shape of a loop having a side that is open, and may partially surround (e.g., around a periphery of) the display area DA.

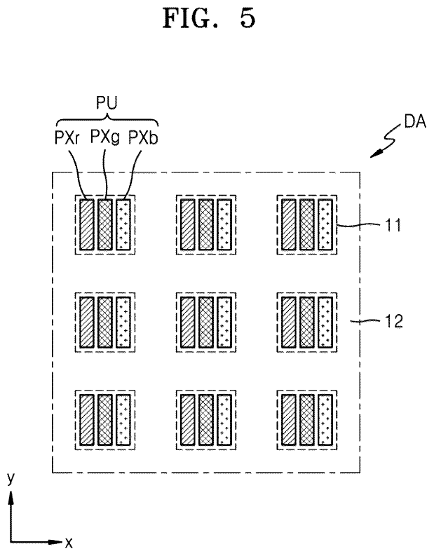

FIG. 5 is a schematic plan view of an arrangement of pixels of a display panel according to an embodiment of the present disclosure.

Referring to FIG. 5, the display area DA may include first areas 11, and a second area 12 surrounding (e.g., around a periphery of) each of the first areas 11. The first areas 11 may be repeatedly arranged along a first direction (e.g., the x direction) and a second direction (e.g., the y direction).

The display area DA may include the first areas 11 and the second area 12 having different elongation rates from each other. For example, the display panel 10 may include the first areas 11 having a relatively low elongation rate, and the second area 12 having a relatively high elongation rate. As used herein, the elongation rate may be a numerical value indicating a change ΔL/L in a length by which the display panel 10 may be stretched without being physically damaged, when an external force is applied to the display panel 10. In this case, ΔL indicates the amount of change in the length of the display panel 10, and L indicates an initial length of the display panel 10. Thus, the elongation rate of each of the first area 11 and the second area 12 may indicate a change in a length of each of the first area 11 and the second area 12, when the same external force is applied to each of the first area 11 and the second area 12.

When the elongation rate of the first area 11 is less than the elongation rate of the second area 12, the first area 11 may be relatively less deformed by an external force than the second area 12. Thus, the first areas 11 may be referred to as a low deformation area, and the second area 12 may be referred to as a high deformation area.

The first areas 11 may be spaced apart from each other, and may be two-dimensionally arranged in the display area DA. The first area 11 may be an area where the pixels are arranged, and thus, the first area 11 may be referred to as a pixel area or an emission area. One or more pixels may be arranged in each of the first areas 11. A pixel unit (e.g., a unit pixel) PU including a plurality of pixels (e.g., a set of pixels) may be provided in the first area 11, and each pixel unit PU may include a red pixel PXr, a green pixel PXg, and a blue pixel PXb.

The second area 12 may be arranged between the first areas 11 adjacent to each other. As illustrated in FIG. 5, in a plan view, the second area 12 may have a shape surrounding (e.g., around a periphery of) each of the first areas 11. The second area 12 may be an area where a connection line for electrically connecting the pixel circuit PC (e.g., see FIG. 4) arranged in each of two adjacent first areas 11 passes.

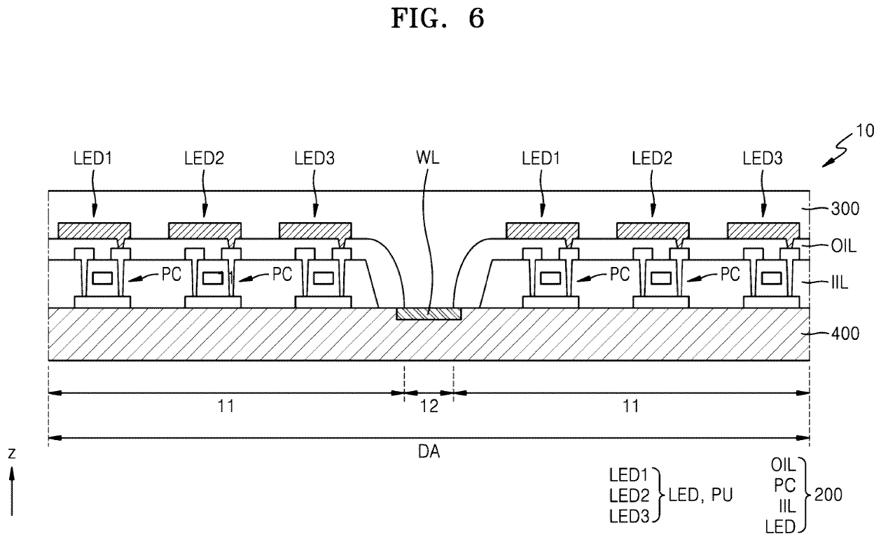

FIG. 6 is a schematic cross-sectional view of a portion of a display panel according to an embodiment of the present disclosure.

Referring to FIG. 6, the display area DA may include the first areas 11 and the second area 12. The second area 12 may be an area connecting the first areas 11 to each other that are arranged adjacent to each other. The first area 11 may have a relatively less elongation rate than that of the second area 12, and may include a light-emitting diode LED and a pixel circuit PC. The second area 12 may have a relatively greater elongation rate than that of the first area 11, and may include a connection line WL included in a signal line to supply a signal to each of the pixel circuits PC.

The first area 11 and the second area 12 may be formed on a base layer 400. In other words, in the base layer 400, each of the first area 11 and the second area 12 may be defined. The light-emitting diode LED and the pixel circuit PC may be arranged in the first area 11 of the base layer 400, and the connection line WL may be arranged in the second area 12 of the base layer 400.

The base layer 400 may absorb a stress that may occur when the display panel 10 is stretched. The base layer 400 may include an elastomer. For example, the base layer 400 may include at least one of a thermoplastic polyurethane, silicone, thermoplastic rubbers, elastolefin, a thermoplastic olefin, polyamide, polyether block amide, synthetic polyisoprene, polybutadiene, a chloroprene rubber, a butyl rubber, styrene-butadiene, an epichlorohydrin rubber, a polyacrylic rubber, a silicone rubber, a fluorosilicone rubber, fluoroelastomers, ethylene-vinyl acetate, polydimethylsiloxane (PDMS), and/or ecoflex.

A display layer 200 may be arranged in the first area 11 of the base layer 400. The display layer 200 may include an inorganic insulating layer IIL, the pixel circuit PC, an organic insulating layer OIL, and the light-emitting diode LED. The pixel circuit PC may be arranged on the base layer 400, and the inorganic insulating layer IIL may be arranged between electrodes included in the pixel circuit PC. The organic insulating layer OIL may be arranged on the inorganic insulating layer IIL to cover the pixel circuit PC. The light-emitting diode LED may be arranged on the organic insulating layer OIL, and may be electrically connected to a corresponding pixel circuit PC. The inorganic insulating layer IIL may include an inorganic insulating material, such as silicon nitride and/or silicon oxide, and the organic insulating layer OIL may include an organic insulating material, such as polyimide.

According to an embodiment, one pixel unit (e.g., one unit pixel) PU may be arranged in one first area 11. The pixel unit PU may include a red pixel PXr (e.g., see FIG. 5), a green pixel PXg, and a blue pixel PXb, as described above. The red pixel PXr may include a first light-emitting diode LED1, the green pixel PXg may include a second light-emitting diode LED2, and the blue pixel PXb may include a third light-emitting diode LED3. For example, the first light-emitting diode LED1 may emit red light, the second light-emitting diode LED2 may emit green light, and the third light-emitting diode LED3 may emit blue light. According to some embodiments, the light-emitting diode LED may emit white light.

The connection line WL may be arranged in the second area 12 of the base layer 400. According to an embodiment, as illustrated in FIG. 6, the connection line WL may be arranged on the base layer 400, and may be arranged at a relatively lower position than that of the display layer 200. In other words, the base layer 400 may be arranged to cover the connection line WL arranged on a rear surface of the display layer 200. Thus, a thickness of the base layer 400 corresponding to the second area 12 may be less than a thickness of the base layer 400 corresponding to the first area 11. However, the present disclosure is not limited thereto, and according to another embodiment, the connection line WL may be arranged on the base layer 400, and may be arranged at (e.g., in or on) the same or substantially the same layer as some of the layers of the display layer 200.

The connection line WL may include a suitable material having both excellent flexibility and electrical characteristics. According to an embodiment, the connection lines WL arranged in the second area 12 may include a liquid metal. According to another embodiment, the connection lines WL may include a metal nanostructure and an elastic polymer. According to another embodiment, the connection lines WL may include a conductive composite material including an elastomer.

According to an embodiment, a protective layer 300 may be arranged on the light-emitting diode LED. The protective layer 300 may be arranged in both of the first area 11 and the second area 12. In other words, the protective layer 300 may be arranged to cover the entire display area DA. The protective layer 300 may cover the light-emitting diode LED and the connection line WL. The protective layer 300 may absorb a stress that may occur when the display panel 10 is stretched. In more detail, the protective layer 300 may prevent or substantially prevent the stress that may occur when the display panel 10 is stretched from being delivered to the light-emitting diode LED and the pixel circuit PC.

The protective layer 300 may include an elastomer. The protective layer 300 may include at least one of a thermoplastic polyurethane, silicone, thermoplastic rubbers, elastolefin, a thermoplastic olefin, polyamide, polyether block amide, synthetic polyisoprene, polybutadiene, a chloroprene rubber, a butyl rubber, styrene-butadiene, an epichlorohydrin rubber, a polyacrylic rubber, a silicone rubber, a fluorosilicone rubber, fluoroelastomers, ethylene-vinyl acetate, PDMS, and/or ecoflex. According to an embodiment, the protective layer 300 may include the same material as that of the base layer 400. However, the present disclosure is not limited thereto, and the protective layer 300 may include a different material from that of the base layer 400.

FIGS. 7A through 7C are each an equivalent circuit diagram of a pixel of a display panel according to some embodiments of the present disclosure.

Referring to FIG. 7A, the light-emitting diode LED corresponding to the pixel may be electrically connected to the pixel circuit PC. The pixel circuit PC may include a first transistor T1, a second transistor T2, and a storage capacitor Cst. The pixel circuit PC may be electrically connected to a signal line and a voltage line. The signal line may include the gate line GL (e.g., see FIG. 4), such as a scan signal line GWL, and the data line DL. The voltage line may include a first voltage line VDDL. The first voltage line VDDL may be connected to the driving voltage supply line W11 (e.g., see FIG. 4), and a second voltage line VSSL may be connected to the common voltage supply line W13 (e.g., see FIG. 4).

The second transistor T2 may be electrically connected to the scan signal line GWL and the data line DL. The scan signal line GWL may provide a scan signal GW to a gate electrode of the second transistor T2. The second transistor T2 may transmit a data signal Dm input from the data line DL to the first transistor T1, according to the scan signal GW input from the scan signal line GWL.

The storage capacitor Cst may be electrically connected to the second transistor T2 and the first voltage line VDDL, and may store a voltage corresponding to a difference between a voltage transmitted from the second transistor T2 and a first power voltage VDD supplied by the first voltage line VDDL.

The first transistor T1 may include a driving transistor, and may control a driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED, according to a value of the voltage stored in the storage capacitor Cst. The light-emitting diode LED may emit light having a desired brightness (e.g., a certain or predetermined brightness) according to the driving current. A first electrode of the light-emitting diode LED may be electrically connected to the first transistor T1, and a second electrode of the light-emitting diode LED may be electrically connected to a second voltage line VSSL that supplies a second power voltage VSS.

FIG. 7A illustrates that the pixel circuit PC may include two transistors and one storage capacitor. However, according to another embodiment, the pixel circuit PC may include three or more transistors.

Referring to FIG. 7B, the pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC may be electrically connected to signal lines and voltage lines. The signal lines may include the gate line GL (e.g., see FIG. 4), such as the scan signal line GWL, a bypass control line GBL, an initialization control line GIL, and an emission control line EML, and the data line DL. The voltage lines may include first and second initialization voltage lines VIL1 and VIL2 and the first voltage line VDDL. The first voltage line VDDL may be connected to the driving voltage supply line W11 (e.g., see FIG. 4), and the second voltage line VSSL may be connected to the common voltage supply line W13 (e.g., see FIG. 4).

The first voltage line VDDL may transmit a first power voltage VDD to the first transistor T1. The first initialization voltage line VIL1 may transmit a first initialization voltage Vint for initializing the first transistor T1 to the pixel circuit PC. The second initialization voltage line VIL2 may transmit a second initialization voltage Vaint for initializing the first electrode of the light-emitting diode LED to the pixel circuit PC.

The first transistor T1 may be electrically connected to the first voltage line VDDL through the fifth transistor T5, and may be electrically connected to the light-emitting diode LED through the sixth transistor T6. The first transistor T1 may function as a driving transistor, and may receive a data signal Dm to transmit a driving current to the light-emitting diode LED according to a switching operation of the second transistor T2.

The second transistor T2 may include a data write transistor, and may be electrically connected to the scan signal line GWL and the data line DL. The second transistor T2 may be electrically connected to the first voltage line VDDL through the fifth transistor T5. The second transistor T2 may be turned on according to a scan signal GW received through the scan signal line GWL, and may perform a switching operation for transmitting the data signal Dm transmitted through the data line DL to a first node N1.

The third transistor T3 may be electrically connected to the scan signal line GWL, and may be electrically connected to the light-emitting diode LED through the sixth transistor T6. The third transistor T3 may be turned on according to a scan signal GW received through the scan signal line GWL, and may diode-connect the first transistor T1.

The fourth transistor T4 may include a first initialization transistor, and may be electrically connected to the initialization control line GIL and the first initialization voltage line VIL1. The fourth transistor T4 may be turned on according to an initialization control signal GI received through the initialization control line GIL, and may transmit the first initialization voltage Vint from the first initialization voltage line VIL1 to a gate electrode of the first transistor T1 to initialize a voltage of the gate electrode of the first transistor T1. The initialization control signal GI may correspond to a scan signal of another pixel circuit arranged in a previous row of the corresponding pixel circuit PC.

The fifth transistor T5 may include an operation control transistor, and the sixth transistor T6 may include an emission control transistor. The fifth transistor T5 and the sixth transistor T6 may be electrically connected to the emission control line EML, and may be concurrently (e.g., simultaneously or substantially simultaneously) turned on with each other according to an emission control signal EM received through the emission control line EML to form a current path through which a driving current may flow in a direction from the first voltage line VDDL toward the light-emitting diode LED.

The seventh transistor T7 may include a second initialization transistor, and may be electrically connected to the bypass control line GBL, the second initialization voltage line VIL2, and the sixth transistor T6. The seventh transistor T7 may be turned on according to a bypass control signal GB received through the bypass control line GBL, and may transmit the second initialization voltage Vaint from the second initialization voltage line VIL2 to the first electrode of the light-emitting diode LED to initialize the first electrode of the light-emitting diode LED.

The storage capacitor Cst may include a first electrode CE1 and the second electrode CE2. The first electrode CE1 may be electrically connected to the gate electrode of the first transistor T1, and the second electrode CE2 may be electrically connected to the first voltage line VDDL. The storage capacitor Cst may store and sustain a voltage corresponding to a difference between a voltage of the first voltage line VDDL and a voltage of the gate electrode of the first transistor T1, so as to sustain a voltage applied to the gate electrode of the first transistor T1.

Referring to FIG. 7C, the pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include the gate line GL (e.g., see FIG. 4), such as the scan signal line GWL, the bypass control line GBL, the initialization control line GIL, and the emission control line EML, and the data line DL. The voltage lines may include the first and second initialization voltage lines VIL1 and VIL2, a sustaining voltage line VSL, and the first voltage line VDDL. The first voltage line VDDL may be connected to the driving voltage supply line W11 (e.g., see FIG. 4), and the second voltage line VSSL may be connected to the common voltage supply line W13.

The first voltage line VDDL may transmit a first power voltage VDD to the first transistor T1. The first initialization voltage line VIL1 may transmit a first initialization voltage Vint for initializing the first transistor T1 to the pixel circuit PC. The second initialization voltage line VIL2 may transmit a second initialization voltage Vaint for initializing the first electrode of the light-emitting diode LED to the pixel circuit PC. The sustaining voltage line VSL may provide a sustaining voltage VSUS to a second node N2, for example, such as to a second electrode CE2 of the storage capacitor Cst, in an initialization section and a data write section.

The first transistor T1 may be electrically connected to the first voltage line VDDL through the fifth transistor T5 and the eighth transistor T8, and may be electrically connected to the light-emitting diode LED through the sixth transistor T6. The first transistor T1 may function as a driving transistor, and may receive a data signal Dm to transmit a driving current to the light-emitting diode LED according to a switching operation of the second transistor T2.

The second transistor T2 may be electrically connected to the scan signal line GWL and the data line DL, and may be electrically connected to the first voltage line VDDL through the fifth transistor T5 and the eighth transistor T8. The second transistor T2 may be turned on according to a scan signal GW received through the scan signal line GWL, and may perform a switching operation of transmitting the data signal Dm transmitted through the data line DL to a first node N1.

The third transistor T3 may be electrically connected to the scan signal line GWL, and may be electrically connected to the light-emitting diode LED through the sixth transistor T6. The third transistor T3 may be turned on according to the scan signal GW received through the scan signal line GWL, and may diode-connect the first transistor T1 to compensate for a threshold voltage of the first transistor T1.

The fourth transistor T4 may be electrically connected to the initialization control line GIL and the first initialization voltage line VIL1, and may be turned on according to an initialization control signal GI received through the initialization control line GIL to transmit the first initialization voltage Vint from the first initialization voltage line VIL1 to a gate electrode of the first transistor T1 to initialize a voltage of the gate electrode of the first transistor T1. The initialization control signal GI may correspond to a scan signal of another pixel circuit arranged in a previous row of the corresponding pixel circuit PC.

The fifth transistor T5, the sixth transistor T6, and the eighth transistor T8 may be electrically connected to the emission control line EML, and may be concurrently (e.g., simultaneously or substantially simultaneously) turned on with each other according to an emission control signal EM received through the emission control line EML to form a current path through which a driving current may flow in a direction from the first voltage line VDDL toward the light-emitting diode LED.

The seventh transistor T7 may include a second initialization transistor, and may be electrically connected to the bypass control line GBL, the second initialization voltage line VIL2, and the sixth transistor T6. The seventh transistor T7 may be turned on according to a bypass control signal GB received through the bypass control line GBL, and may transmit the second initialization voltage Vaint from the second initialization voltage line VIL2 to the first electrode of the light-emitting diode LED to initialize the first electrode of the light-emitting diode LED.

The ninth transistor T9 may be electrically connected to the bypass control line GBL, the second electrode CE2 of the storage capacitor Cst, and the sustaining voltage line VSL. The ninth transistor T9 may be turned on according to a bypass control signal GB transmitted through the bypass control line GBL, and may transmit the sustaining voltage VSUS to a second node N2, for example, such as to the second electrode CE2 of the storage capacitor Cst, in an initialization section and a data write section.

Each of the eighth transistor T8 and the ninth transistor T9 may be electrically connected to the second node N2, for example, such as to the second electrode CE2 of the storage capacitor Cst. According to some embodiments, in the initialization section and the data write section, the eighth transistor T8 may be turned off and the ninth transistor T9 may be turned on, and in an emission section, the eighth transistor T8 may be turned on and the ninth transistor T9 may be turned off. The sustaining voltage VSUS may be transmitted to the second node N2 in the initialization section and the data write section, and thus, a uniformity of the brightness (e.g., a long range uniformity (LRU)) of the display apparatus according to a voltage drop of the first voltage line VDDL may be improved.

The storage capacitor Cst may include a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustaining voltage line VSL, and the first electrode of the light-emitting diode LED. The auxiliary capacitor Ca may store and sustain a voltage corresponding to a difference between voltages of the first electrode of the light-emitting diode LED and the sustaining voltage line VSL, while the seventh transistor T7 and the ninth transistor T9 are being turned on, and thus, the auxiliary capacitor Ca may prevent or substantially prevent an increase in a black brightness when the sixth transistor T6 is turned off.

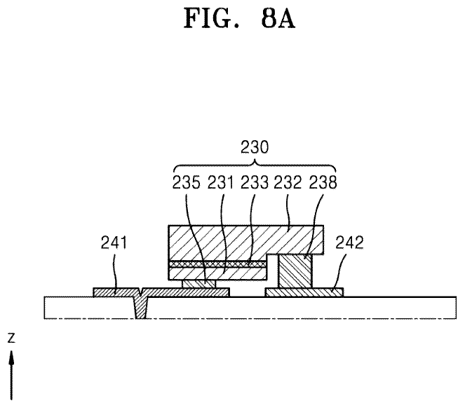

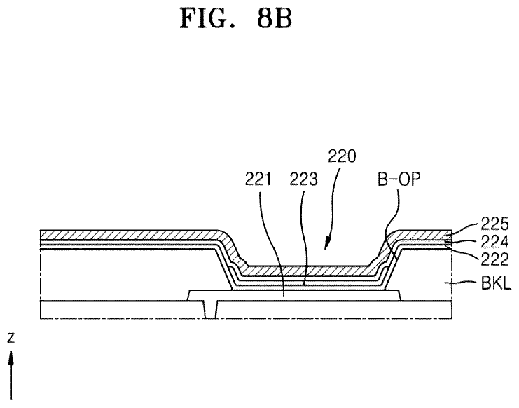

FIGS. 8A and 8B are each a schematic cross-sectional view of a light-emitting diode of a display panel according to some embodiments of the present disclosure.

Referring to FIG. 8A, the light-emitting diode LED (e.g., see FIG. 7A) may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively and electrically connected to a first electrode pad 241 and a second electrode pad 242, which are arranged at (e.g., in or on) the same layer as each other. The second electrode pad 242 may be a portion of the second voltage line VSSL (e.g., see FIG. 7A), or a conductive layer electrically connected to the second voltage line VSSL.

According to some embodiments, the first conductive layer 231 may include a p-type semiconductor layer. The p-type semiconductor layer may include a semiconductor material having a composition of InₓAl_{y}Ga_{1-x-y}N (0≤x≤1, 0≤y≤1, and 0≤x+y≤1), for example, such as a material selected from among GaN, AlN, AlGaN, InGaN, InN, InAlGaN, AlInN, and/or the like, and may be doped with a p-type dopant, such as Mg, Zn, Ca, Sr, Ba, and/or the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, and 0≤x+y≤1), for example, such as a material selected from among GaN, AlN, AlGaN, InGaN, InN, InAlGaN, AlInN, and/or the like, and may be doped with an n-type dopant, such as Si, Ge, Sn, and/or the like.

The intermediate layer 233 may be where electrons and holes reunite, and when the electrons and the holes reunite, a transition to a reduced energy level may be performed to generate light having a wavelength corresponding to the reduced energy level. The intermediate layer 233 may include, for example, a semiconductor material having a composition of InₓAl_{y}Ga_{1-x-y}N (0≤x≤1, 0≤y≤1, and 0≤x+y≤1), and may be formed as a single quantum well structure or a multi-quantum well (MQW) structure. Also, the intermediate layer 233 may include a quantum wire structure or a quantum dot structure.

In FIG. 8A, it has been illustrated that the first semiconductor layer 231 may include the p-type semiconductor layer and the second semiconductor layer 232 may include the n-type semiconductor layer. However, the present disclosure is not limited thereto. According to another embodiment, the first semiconductor layer 231 may include an n-type semiconductor layer, and the second semiconductor layer 232 may include a p-type semiconductor layer.

Referring to FIG. 8B, the light-emitting diode LED (e.g., see FIG. 7A) may include an organic light-emitting diode 220 including an organic material. The organic light-emitting diode 220 may include a first electrode 221 arranged on an insulating layer, a second electrode 225 facing or opposite to the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered by a bank layer BKL including an insulating material. The bank layer BKL may include an opening B-OP overlapping with a central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the first electrode 221 may include a reflective layer including Ag, Mg, Al, Pt, Pd, Au, Ni, Nd, Ir, Cr, or a suitable compound thereof. According to another embodiment, the first electrode 221 may further include a layer including ITO, IZO, ZnO, AZO, or In₂O₃ above/under the reflective layer described above.

The emission layer 223 may include a high or low molecular-weight organic material for emitting light of a desired color (e.g., a certain or predetermined color). The first functional layer 221 may include a hole transport layer (HTL) and/or a hole injection layer (HIL). The second functional layer 224 may include an electron transport layer and/or an electron injection layer.

The second electrode 225 may include a conductive material having a low work function. For example, the second electrode 225 may include a transparent (semi-transparent) layer including Ag, Mg, Al, Pt, Pd, Au, Ni, Nd, Ir, Cr, Li, Ca, or a suitable alloy thereof. As another example, the second electrode 225 may further include a layer, such as ITO, IZO, ZnO, AZO, or In₂O₃, on the transparent (semi-transparent) layer including one or more of the materials described above.

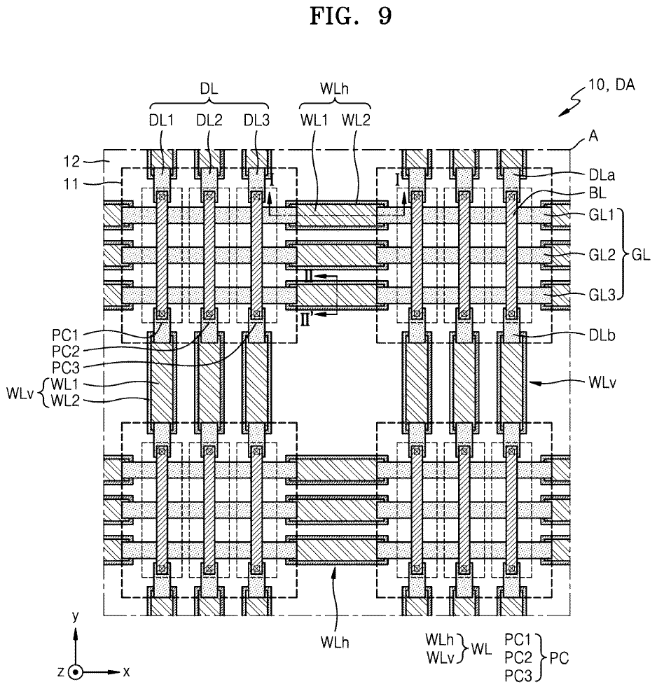

FIG. 9 is a schematic plan view of a portion of a display panel according to an embodiment of the present disclosure. For example, FIG. 9 is a schematic plan view of the region A of the display panel of FIG. 4.

Referring to FIG. 9, the display area DA may include the plurality of first areas 11, and the second area 12 surrounding (e.g., around peripheries of) the plurality of first areas 11. The first area 11 may have a less elongation rate than that of the second area 12. Accordingly, when the display panel 10 is stretched or compressed, the first area 11 may be less deformed than the second area 12. The first area 11 may be referred to as a low deformation area (e.g., a low deformation portion) as described above. Also, the first area 11 may be an area where the light-emitting diodes are arranged and may be referred to as a pixel area or an emission area.

The second area 12 may surround (e.g., around a periphery of) the first area 11, and may have a greater elongation rate than that of the first area 11. The second area 12 may be an area where a main deformation occurs according to the stretching or compression of a display apparatus. The second area 12 may be arranged between the plurality of first areas 11, and thus, may be referred to as a connection portion for connecting the first areas 11 to each other. Also, the second area 12 may be referred to as a main deformation area (e.g., a main deformation portion) or a high deformation area (e.g., a high deformation portion). The second area 12 may be an area where the light-emitting diode is not arranged in the display area and may be referred to as a non-pixel area or a non-emission area.

The pixel circuits PC configured to drive the light-emitting diodes of the pixels may be arranged in the first area 11. For example, a first pixel circuit PC1 of the red pixel PXr (e.g., see FIG. 5), a second pixel circuit PC2 of the green pixel PXg, and a third pixel circuit PC3 of the blue pixel PXb may be arranged in the first area 11. Each of the first pixel circuit PC1, the second pixel circuit PC2, and the third pixel circuit PC3 may include a transistor and a capacitor, like the pixel circuits PC described above with reference to FIGS. 7A to 7C.

Lines electrically connected to the pixel circuit PC may be arranged in the display area DA. The lines may include a voltage line or a signal line. According to an embodiment, FIG. 9 illustrates that each of the gate line GL and the data line DL is arranged in the first area 11. Each of the gate line GL and the data line DL may be electrically connected to the pixel circuit PC through a corresponding contact hole.

The gate line GL of FIG. 9 may provide a gate signal to a gate electrode of a transistor. According to an embodiment, the gate line GL may include a first gate line GL1, a second gate line GL2, and a third gate line GL3. The first to third gate lines GL1, GL2, and GL3 extending in a first direction (e.g., the x direction) may be connected to each of the pixel circuits PC arranged in the same row as each other and may transmit different gate signals from each other. For example, the gate line GL of FIG. 9 may correspond to the scan signal line GWL, the bypass control line GBL, the initialization control line GIL, and/or the emission control line EML of FIG. 7B or FIG. 7C.

The data line DL of FIG. 9 may provide a data signal to each pixel circuit PC. The data line DL extending in a second direction (e.g., the y direction) may be electrically connected to the pixel circuits PC arranged in the same column as each other. According to an embodiment, the data line DL may include a first data line DL1 electrically connected to the first pixel circuit PC1, a second data line DL2 electrically connected to the second pixel circuit PC2, and a third data line DL3 electrically connected to the third pixel circuit PC3.

Two signal lines that are adjacent to each other and respectively arranged in two first areas 11 adjacent to each other may be electrically connected to each other by the connection line WL. In more detail, two data lines DL that are adjacent to each other and respectively arranged in two first areas 11 adjacent to each other may be electrically connected to each other by a vertical connection line WLv. The vertical connection line WLv may be arranged in the second area 12, and may extend in the second direction (e.g., the y direction). Each of the data lines DL arranged at opposite sides from each other with the vertical connection line WLv therebetween may be in contact with the vertical connection line WLv.

Two gate lines GL that are adjacent to each other and respectively arranged in two first areas 11 adjacent to each other may be electrically connected to each other by a horizontal connection line WLh. The horizontal connection line WLh may be arranged in the second area 12, and may extend in the first direction (e.g., the x direction). Each of the gate lines GL arranged at opposite sides from each other with the horizontal connection line WLh therebetween may be in contact with the horizontal connection line WLh.

The gate line GL and the data line DL may cross each other in the first area 11. According to an embodiment, the data line DL may include a first portion DLa and a second portion DLb spaced apart (e.g., separated) from each other with the gate line GL therebetween, and a bridge line BL arranged between the first portion DLa and the second portion DLb. The first portion DLa and the second portion DLb may be electrically connected to each other by the bridge line BL.

The bridge line BL may be arranged at an area where the data line DL and the gate line GL cross each other, and may connect the first portion DLa of the data line DL to the second portion DLb of the data line DL. The bridge line BL may be arranged at (e.g., in or on) a different layer from those of the first portion DLa and the second portion DLb. An end of the bridge line BL may be connected to the first portion DLa through a contact hole, and another end (e.g., an opposite end) of the bridge line BL may be connected to the second portion DLb through a contact hole.

FIG. 9 illustrates that the data line DL is connected through the first portion DLa, the second portion DLb, and the bridge line BL. However, the present disclosure is not limited thereto. According to another embodiment, the gate line GL may be separated into a first portion and a second portion, which may be connected to each other through a bridge line.

The vertical connection line WLv and the horizontal connection line WLh arranged in the second area 12 may be more stretchable than the gate line GL and the data line DL arranged in the first area 11. An elongation rate of each of the vertical connection line WLv and the horizontal connection line WLh may be greater than an elongation rate of each of the gate line GL and the data line DL.

Each of the gate line GL and the data line DL may include one or more suitable materials selected from Al, Pt, Pd, Ag, Mg, Au, Ni, Nd, Ir, Cr, Li, Ca, Mo, Ti, W, and/or Cu. According to some embodiments, each of the gate line GL and the data line DL may include a single layer or multi-layers including one or more metals described above. According to an embodiment, each of the gate line GL and the data line DL may include a metal thin layer including a triple layer structure having a Ti/Al/Ti structure.

FIG. 9 illustrates that the gate line GL and the data line DL are respectively and electrically connected to the horizontal connection line WLh and the vertical connection line WLv. However, the present disclosure is not limited thereto. According to another embodiment, the first initialization voltage line VIL1, the second initialization voltage line VIL2, the sustaining voltage line VSL, the first voltage line VDDL, or the second voltage line VSSL described above with reference to FIGS. 7A to 7C may each be arranged in the first area 11, and may be electrically connected to a connection line arranged in the second area 12.

According to an embodiment, each of the vertical connection line WLv and the horizontal connection line WLh may include a suitable structure in which a first connection line WL1 and a second connection line WL2 are stacked. For example, the connection line WL may include a structure in which the first connection line WL1 is arranged on the second connection line WL2, as illustrated in FIG. 9. The second connection line WL2 may be arranged below (e.g., under) the first connection line WL1, and may cover up to a side surface of the first connection line WL1.

The first connection line WL1 and the second connection line WL2 may have different electrical characteristics from each other. According to an embodiment, the first connection line WL1 and the second connection line WL2 may have resistance variation rates according to different elongation rates. In more detail, compared to the second connection line WL2, the first connection line WL1 may include a suitable material having a less initial resistance in an undeformed state and a higher resistance variation rate according to an elongation rate. Compared to the first connection line WL1, the second connection line WL2 may include a suitable material having a greater initial resistance in an undeformed state and a lower resistance variation rate according to an elongation rate. For example, the first connection line WL1 may include an Ag flake-PDMS composite, and the second connection line WL2 may include an Ag nanowire. In other words, the first connection line WL1 may include a highly conductive material, and the second connection line WL2 may include a highly flexible material.

In other words, in a non-elongated state, the initial resistance of the first connection line WL1 may be less than the initial resistance of the second connection line WL2, and thus, in an undeformed state or a low deformation state, the first connection line WL1 may perform a main line role of the connection line WL. In a high deformation state, because the resistance variation rate of the second connection line WL2 according to the elongation rate may be low, the resistance of the second connection line WL2 may be less than the resistance of the first connection line WL1. Thus, in the highly deformed state, the second connection line WL2 may perform a main line role of the connection line WL.

When the connection line WL includes a single material, for example, such as that of the first connection line WL1, the initial resistance in an undeformed state may be low, but the resistance variation in a high deformation state may be high, which may cause a problem. Likewise, when the connection line WL includes a single material, for example, such as that of the second connection line WL2, the resistance variation in a high deformation state may not be great, but the initial resistance in an undeformed state may be high, and thus, an efficiency may be reduced.

The connection line WL includes the structure in which the first connection line WL1 and the second connection line WL2 are stacked, and the first connection line WL1 and the second connection line WL2 may have the resistance variation rates according to the different elongation rates, and thus, the resistance variation of the connection line WL according to the elongation rate may be minimized or reduced so as to maintain or substantially maintain excellent electrical characteristics. In other words, according to an embodiment of the present disclosure, the display panel 10 may have an improved flexibility, and may realize a high-quality image even in a high deformation state through the connection line WL having the structure as described above.

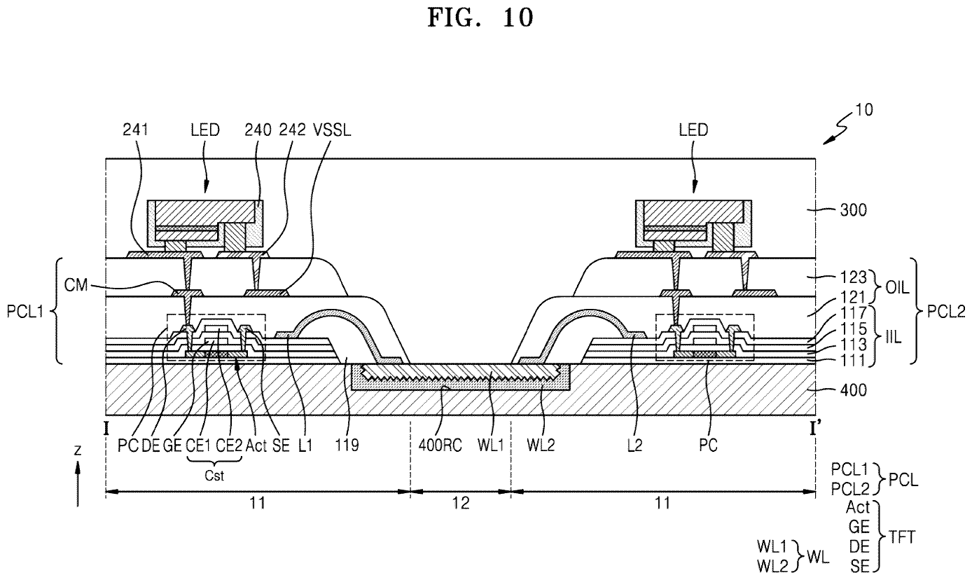

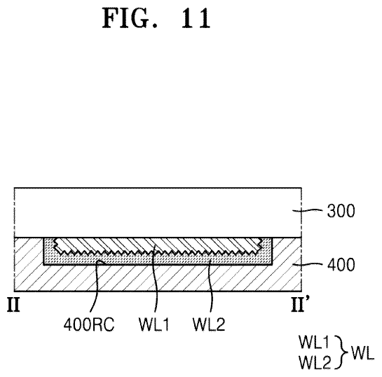

FIG. 10 is a schematic cross-sectional view of a portion of a display panel taken along the line I-I′ of FIG. 9 according to an embodiment of the present disclosure. FIG. 11 is a schematic cross-sectional view of a portion of a display panel taken along the line II-II′ of FIG. 9 according to an embodiment of the present disclosure.

Referring to FIG. 10, the display panel 10 may include the first areas 11 and the second area 12 between the first areas 11 as described above with reference to FIG. 9. The elements of the display panel 10 may be arranged on the base layer 400, and thus, the display panel 10 including the first areas 11 and the second area 12 may correspond to the base layer 400 including the first areas 11 and the second area 12.

The display panel 10 may include a pixel circuit layer PCL arranged in each of two adjacent first areas 11, and a light-emitting diode LED on each of the pixel circuit layers PCL. Each of the light-emitting diodes LED illustrated in FIG. 10 may correspond to any one of the first to third light-emitting diodes LED1 to LED3 illustrated in FIG. 6.

Each pixel circuit layer PCL may include an inorganic insulating stack IIL, a pixel circuit PC, and an organic insulating layer OIL. Hereinafter, for convenience of illustration, one of the pixel circuit layers PCL arranged in the two adjacent first areas 11 may be referred to as a first pixel circuit layer PCL1, and another one may be referred to as a second pixel circuit layer PCL2.

Each of the first pixel circuit layer PCL1 and the second pixel circuit layer PCL2 may be arranged on the base layer 400. Each of the first pixel circuit layer PCL1 and the second pixel circuit layer PCL2 may be arranged on a first surface (e.g., an upper surface) of the base layer 400.

The base layer 400 may absorb a stress occurring when the display panel 10 is stretched. The base layer 400 may include an elastomer. The base layer 400 may include at least one of a thermoplastic polyurethane, silicone, thermoplastic rubbers, elastolefin, a thermoplastic olefin, polyamide, polyether block amide, synthetic polyisoprene, polybutadiene, a chloroprene rubber, a butyl rubber, styrene-butadiene, an epichlorohydrin rubber, a polyacrylic rubber, a silicone rubber, a fluorosilicone rubber, fluoroelastomers, ethylene-vinyl acetate, PDMS, and/or ecoflex.

Each of the first pixel circuit layer PCL1 and the second pixel circuit layer PCL2 may include the inorganic insulating stack IIL, the pixel circuit PC, and the organic insulating layer OIL. The inorganic insulating stack IIL may include a buffer layer 111, a gate insulating layer 113, a first interlayer insulating layer 115, and a second interlayer insulating layer 117. The organic insulating layer OIL may include a first organic insulating layer 121 and a second organic insulating layer 123.

The first pixel circuit layer PCL1 and the second pixel circuit layer PCL2 may be arranged to be spaced apart from each other. The first pixel circuit layer PCL1 and the second pixel circuit layer PCL2 being arranged to be spaced apart from each other may denote that the inorganic insulating stack IIL, the pixel circuit PC, and the organic insulating layer OIL of the first pixel circuit layer PCL1 are arranged to be spaced apart from the inorganic insulating stack IIL, the pixel circuit PC, and the organic insulating layer OIL of the second pixel circuit layer PCL2, respectively.

The inorganic insulating stack IIL may be arranged in the first area 11 and may not be arranged in the second area 12. The inorganic insulating stack IIL may be arranged in the first area 11 in an isolated shape (e.g., an island shape). The inorganic insulating stacks IIL respectively arranged in the first areas 11 may be spaced apart from each other in a plan view. For example, the buffer layer 111, the gate insulating layer 113, the first interlayer insulating layer 115, and the second interlayer insulating layer 117 of the first pixel circuit layer PCL1 may be respectively separated from the buffer layer 111, the gate insulating layer 113, the first interlayer insulating layer 115, and the second interlayer insulating layer 117 of the second pixel circuit layer PCL2.

Likewise, the organic insulating layer OIL may be arranged in the first area 11 and may not be arranged in the second area 12. The organic insulating layer OIL may be arranged in the first area 11 in an isolated shape (e.g., an island shape). For example, the first organic insulating layer 121 and the second organic insulating layer 123 of the first pixel circuit layer PCL1 may be respectively separated from the first organic insulating layer 121 and the second organic insulating layer 123 of the second pixel circuit layer PCL2.

As illustrated in FIG. 10, the buffer layer 111 may be arranged on the base layer 400, and the pixel circuit PC may be arranged on the buffer layer 111. The buffer layer 111 may include an inorganic insulating material, such as silicon oxide, silicon nitride, and/or silicon oxynitride.

A thin-film transistor TFT of the pixel circuit PC may include a semiconductor layer Act, a gate electrode GE, a source electrode SE, and a drain electrode DE. FIG. 10 illustrates a top-gate kind in which the gate electrode GE is arranged above the semiconductor layer Act with the gate insulating layer 113 therebetween. However, according to another embodiment, the thin-film transistor TFT may include a bottom-gate kind.

The semiconductor layer Act may include polysilicon. As another example, the semiconductor layer Act may include amorphous silicon, an oxide semiconductor, an organic semiconductor, or the like. The gate electrode GE may include a metal thin layer including a low-resistance metal material. The gate electrode GE may include a conductive material including Mo, Al, Cu, Ti, or the like, and may include multi-layers or a single layer including one or more of the materials described above. For example, the gate electrode GE may include a metal thin layer including a triple layer structure having a Ti/Al/Ti structure.

The gate insulating layer 113 between the semiconductor layer Act and the gate electrode GE may include an inorganic insulating material, such as silicon oxide, silicon nitride, silicon oxynitride, aluminum oxide, titanium oxide, and/or the like. The gate insulating layer 113 may include a single layer or multi-layers including one or more of the materials described above.

The source electrode SE and the drain electrode DE may be arranged on the same layer as each other, for example, on the second interlayer insulating layer 117, and may include the same material as each other. The source electrode SE and the drain electrode DE may include a metal thin layer including a low-resistance metal material. The source electrode SE and the drain electrode DE may include a conductive material including Mo, Al, Cu, Ti, or the like, and may include multi-layers or a single layer including one or more of the materials described above. For example, the source electrode SE and the drain electrode DE may include a metal thin layer including a triple layer structure having a Ti/Al/Ti structure, like that of the gate electrode GE. The second interlayer insulating layer 117 may include an inorganic insulating material, such as silicon oxide, silicon nitride, silicon oxynitride, aluminum oxide, titanium oxide, and/or the like, and may include a single layer or multi-layers including one or more of the materials described above.

The storage capacitor Cst may include the first electrode CE1 and the second electrode CE2 overlapping with each other with the first interlayer insulating layer 115 therebetween. The storage capacitor Cst may overlap with the thin-film transistor TFT. For example, FIG. 7 illustrates that the gate electrode GE of the thin-film transistor TFT may correspond to the first electrode CE1 of the storage capacitor Cst. According to another embodiment, the storage capacitor Cst may not overlap with the thin-film transistor TFT. The storage capacitor Cst may be covered by the second interlayer insulating layer 117.

The first interlayer insulating layer 115 may be arranged between the gate insulating layer 113 and the second interlayer insulating layer 117. Each of the first interlayer insulating layer 115 and the second interlayer insulating layer 117 may include an inorganic insulating material, such as silicon oxide, silicon nitride, silicon oxynitride, aluminum oxide, titanium oxide, and/or the like, and may include a single layer or multi-layers including one or more of the materials described above.

The second electrode CE2 of the storage capacitor Cst may include a conductive material and may include multi-layers or a single layer. The second electrode CE2 may include a metal thin layer including a low-resistance metal material. The second electrode CE2 may include a conductive material including Mo, Al, Cu, Ti, or the like, and may include multi-layers or a single layer including one or more of the materials described above. For example, the second electrode CE2 may include a metal thin layer including a triple layer structure having a Ti/Al/Ti structure.

The first organic insulating layer 121 may be arranged on the second interlayer insulating layer 117. The second organic insulating layer 123 may be arranged on the first organic insulating layer 121. A connection electrode CM and the second voltage line VSSL may be arranged on the first organic insulating layer 121. The connection electrode CM may electrically connect the pixel circuit PC with the first electrode pad 241. The second voltage line VSSL may be electrically connected to the second electrode pad 242.

The connection electrode CM and the second voltage line VSSL may include a metal thin layer including a low-resistance metal material. The connection electrode CM and the second voltage line VSSL may include a conductive material including Mo, Al, Cu, Ti, or the like, and may include multi-layers or a single layer including one or more of the materials described above. For example, the connection electrode CM and the second voltage line VSSL may include a metal thin layer including a triple layer structure having a Ti/Al/Ti structure.

The first electrode pad 241 and the second electrode pad 242 may be arranged on the second organic insulating layer 123. The first electrode pad 241 may be electrically connected to the thin-film transistor TFT through the connection electrode CM between the first organic insulating layer 121 and the second organic insulating layer 123.

The light-emitting diode LED on the first electrode pad 241 and the second electrode pad 242 may be the same or substantially the same as the light-emitting diode LED described above with reference to FIG. 8A. According to another embodiment, the light-emitting diode LED may have the structure described above with reference to FIG. 8B. A surface of the light-emitting diode LED may be covered by a protective layer 240 including an organic insulating material.

A first line L1 may include a signal line or a voltage line electrically connected to the pixel circuit PC of the first pixel circuit layer PCL1. A second line L2 may include a signal line or a voltage line electrically connected to the pixel circuit PC of the second pixel circuit layer PCL2. According to an embodiment, the first line L1 and the second line L2 may include the gate line GL or the data line DL described above with reference to FIG. 9. According to another embodiment, the first line L1 and the second line L2 may include the first voltage line VDDL or the second voltage line VSSL described above with reference to FIG. 7A, or may include the first initialization voltage line VIL1, the second initialization voltage line VIL2, the sustaining voltage line VSL, the first voltage line VDDL, or the second voltage line VSSL described above with reference to FIGS. 7B and 7C.

Each of the first line L1 and the second line L2 may be arranged on the interlayer insulating layer 117 and may extend onto the connection line WL. A portion of the first line L1 may be arranged on a corresponding portion of the second interlayer insulating layer 117. Another portion of the first line L1 may extend across the inorganic insulating stack IIL onto the connection line WL and may be in direct contact with the connection line WL. In a third direction (e.g., the z direction), a portion of the first line L1 may be arranged between the second interlayer insulating layer 117 and the first organic insulating layer 121, and another portion of the first line L1 may be arranged between a third organic insulating layer 119 described in more detail below and the first organic insulating layer 121. Likewise, a portion of the second line L2 may be arranged on a corresponding portion of the second interlayer insulating layer 117, and another portion of the second line L2 may extend onto the connection line WL and may be in direct contact with the connection line WL. In the third direction (e.g., the z direction), a portion of the second line L2 may be arranged between the second interlayer insulating layer 117 and the first organic insulating layer 121, and another portion of the second line L2 may be arranged between the third organic insulating layer 119 described in more detail below and the first organic insulating layer 121.

The inorganic insulating stack IIL having the isolated shape (e.g., the island shape) in a plan view may have a step difference with respect to the upper surface of the base layer 400 as illustrated in FIG. 10. According to an embodiment, as illustrated in FIG. 10, the organic insulating layer OIL may further include the third organic insulating layer 119 arranged to cover a side surface of the inorganic insulating stack IIL. The third organic insulating layer 119 may have a closed loop shape in the plan view to cover the side surface of the inorganic insulating stack IIL. The first line Li and the second line L2 may extend across an upper surface of the third organic insulating layer 119 onto to the connection line WL.

As described above, the connection line WL may be arranged in the second area 12. According to an embodiment, the connection line WL may be arranged on a lower surface of the pixel circuit layer PCL. In other words, the base layer 400 may include a recess 400RC that is concave from the upper surface toward a lower surface of the base layer 400, and the connection line WL may be arranged in the recess 400RC.

The connection line WL may include a first surface (e.g., a lower surface) toward the base layer 400, and a second surface (e.g., an upper surface) opposite to the first surface. The second surface (e.g., the upper surface) of the connection line WL may be coplanar with the upper surface of the base layer 400. Thus, a thickness of the base layer 400 overlapping with the connection line WL may be less than a thickness of another portion of the base layer 400 not overlapping with the connection line WL. In other words, the connection line WL may be embedded in the base layer 400, and thus, a stress that may be concentrated in the connection line WL when the display panel 10 is stretched, may be absorbed by the base layer 400.

According to an embodiment, the connection line WL may include a structure in which the first connection line WL1 and the second connection line WL2 having different electrical characteristics from each other are stacked. As described above, the first connection line WL1 may include a suitable material having a less initial resistance in a undeformed state and a higher resistance variation rate according to an elongation rate compared to those of the second connection line WL2. The second connection line WL2 may include a suitable material having a greater initial resistance in the undeformed state and a lower resistance variation rate according to an elongation rate compared to those of the first connection line WL1.

In this case, the first connection line WL1 may perform a main line role in the undeformed state, and thus, a part of the connection line WL directly in contact with the first line L1 and the second line L2 may be the first connection line WL1. In other words, as illustrated in FIG. 10, the first line L1 and the second line L2 may be directly in contact with an upper surface of the first connection line WL1.

However, when the display panel 10 is in a high deformation state, the second connection line WL2 may perform the main line role. Thus, an electrical signal may be transmitted from the first connection line WL1 to the second connection line WL2, and thus, a contact area between the first connection line WL1 and the second connection line WL2 may be maximized or increased.

Referring to FIGS. 10 and 11, according to an embodiment, the second connection line WL2 may cover at least some of side surfaces of the first connection line WL1. For example, when the first connection line WL1 is arranged on the second connection line WL2 as illustrated in FIG. 10, the second connection line WL2 may cover remaining side surfaces except for the upper surface of the first connection line WL1. In other words, the second connection line WL2 may cover a lower surface and four side surfaces of the first connection line WL1. In this case, the contact area between the first connection line WL1 and the second connection line WL2 may not only be increased, but the flexibility of the display panel 10 may also be improved, because the second connection line WL2 may have a higher flexibility than that of the first connection line WL1.

Also, according to an embodiment, an interface in contact with the second connection line WL2 from among the side surfaces of the first connection line WL1 may include a plurality of protrusions toward the second connection line WL2. In more detail, the plurality of protrusions of the first connection line WL1 may protrude in a direction from the first connection line WL1 toward the second connection line WL2, and may have a suitable shape of being stuck in the second connection line WL2. The plurality of protrusions (e.g., tips thereof) of the first connection line WL1 may be arranged to be spaced apart from each other by a uniform or substantially uniform distance. Cross-sections of the plurality of protrusions may have triangular shapes as illustrated in FIG. 10, but the present disclosure is not limited thereto, and the cross-sections thereof may have various suitable shapes.

In the display panel 10 according to an embodiment of the present disclosure, the connection line WL may have the structure as described above, and thus, the contact area between the first connection line WL1 and the second connection line WL2 may be increased, so that the main line role may be efficiently switched between the first connection line WL1 and the second connection line WL2, and the resistance variation rate according to a deformation of the connection line WL may be reduced.

Referring to FIG. 10, the light-emitting diode LED may be arranged on the corresponding pixel circuit layer PCL. For example, the light-emitting diode LED electrically connected to the pixel circuit PC of the first pixel circuit layer PCL1 may be arranged on the first pixel circuit layer PCL1, and the light-emitting diode LED electrically connected to the pixel circuit PC of the second pixel circuit layer PCL2 may be arranged on the second pixel circuit layer PCL2. A surface of each light-emitting diode LED may be covered by the protective layer 240. The protective layer 240 may include an organic insulating material such as polyimide.

The protective layer 300 may be arranged on the light-emitting diode LED and the connection line WL. The protective layer 300 may cover the light-emitting diode LED and the connection line WL. The protective layer 300 may absorb a stress that may be transmitted to the light-emitting diode LED and the connection line WL when the display panel 10 is stretched, and may planarize an upper surface of the display panel 10. The protective layer 300 may include an elastomer. For example, the protective layer 300 may include at least one of a thermoplastic polyurethane, silicone, thermoplastic rubbers, elastolefin, a thermoplastic olefin, polyamide, polyether block amide, synthetic polyisoprene, polybutadiene, a chloroprene rubber, a butyl rubber, styrene-butadiene, an epichlorohydrin rubber, a polyacrylic rubber, a silicone rubber, a fluorosilicone rubber, fluoroelastomers, ethylene-vinyl acetate, PDMS, and/or ecoflex.

The protective layer 300 may be in direct contact with the upper surface of the connection line WL, and may be in direct contact with a portion of the upper surface of the base layer 400. According to an embodiment, when a material of the protective layer 300 is the same as a material of the base layer 400, a bonding force between the protective layer 300 and the base layer 400 may be increased, and thus, the display panel 10 may be more effectively sealed.

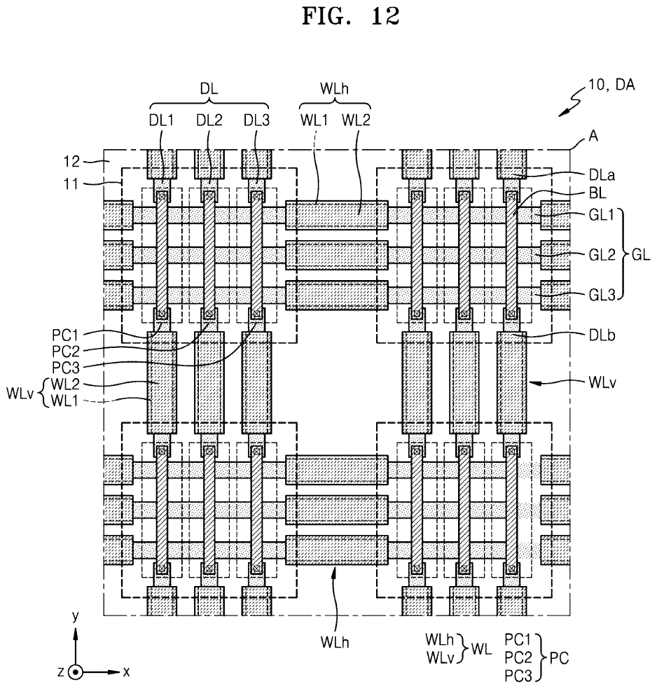

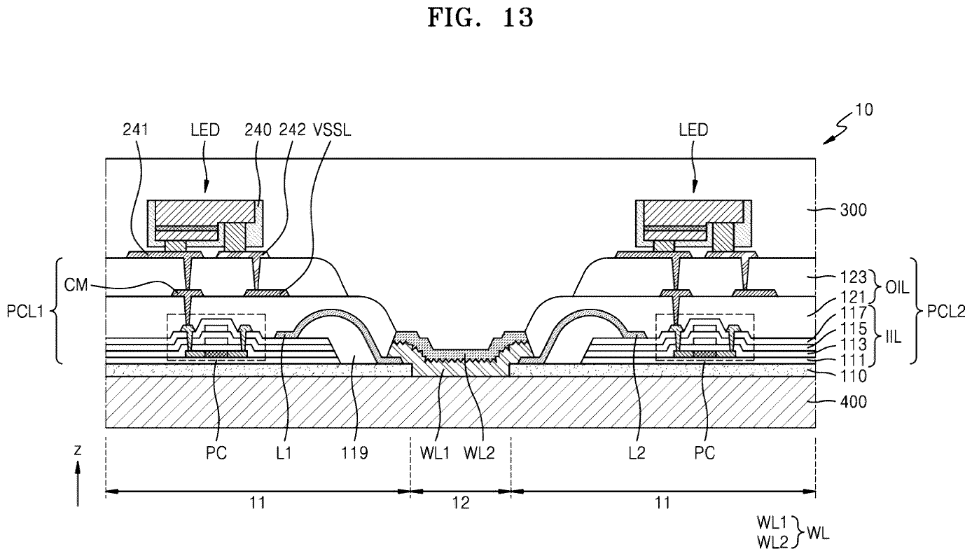

FIG. 12 is a schematic plan view of a portion of a display panel according to an embodiment of the present disclosure. FIG. 13 is a schematic cross-sectional view of a portion of a display panel according to an embodiment of the present disclosure.

Referring to FIGS. 12 and 13, except for the characteristics about the connection line WL, other characteristics are the same as those described above with reference to FIGS. 9 to 11. In FIGS. 12 and 13, the same or substantially the same elements as those described above with reference to FIGS. 9 to 11 are indicated by the same reference numerals, and thus, redundant description thereof may not be repeated and the differences may be mainly described in more detail hereinafter.

Referring to FIGS. 12 and 13, the connection line WL may be arranged in the second area 12. According to an embodiment, the connection line WL may be arranged on a planarized upper surface of the base layer 400. The connection line WL may include the first surface (e.g., the lower surface) toward the base layer 400, and the second surface (e.g., the upper surface) opposite to the first surface. The first surface (e.g., the lower surface) of the connection line WL may be coplanar with the upper surface of the base layer 400.

According to an embodiment, a sub-base layer 110 may be arranged between the base layer 400 and the pixel circuit layers PCL1 and PCL2. In other words, the sub-base layer 110 may be arranged between the base layer 400 and the buffer layer 111. The sub-base layer 110 may include one or more polymer resins. For example, the sub-base layer 110 may include polyether sulfone, polyacrylate, polyether imide, polyethylene naphthalate, polyethylene terephthalate, polyphenylene sulfide, polyarylate, polyimide, polycarbonate, cellulose acetate propionate, or the like.

The sub-base layer 110 may include an opening overlapping with the second area 12, and the connection line WL may be arranged in the opening of the sub-base layer 110. In other words, the connection line WL may be arranged on the upper surface of the base layer 400 that is exposed through the opening of the sub-base layer 110. The connection line WL may not only fill the opening of the sub-base layer 110, but may also be arranged on an upper surface of an end of the sub-base layer 110. In other words, the connection line WL may cover a side surface and a portion of the upper surface of the sub-base layer 110.

According to another embodiment, the sub-base layer 110 may not be arranged between the base layer 400 and the pixel circuit layers PCL1 and PCL2. In other words, the pixel circuit layers PCL1 and PCL2 may be directly arranged on the base layer 400. For example, the upper surface of the base layer 400 and a lower surface of the buffer layer 111 may be directly in contact with each other. In this case, the connection line WL may be directly arranged on the base layer 400. An end of the connection line WL may cover an end of the first line L1 and an end of the second line L2.

According to an embodiment, the connection line WL may include a suitable structure in which the first connection line WL1 and the second connection line WL2 are stacked. For example, the connection line WL may include a structure in which the second connection line WL2 is arranged on the first connection line WL1 as illustrated in FIG. 13. The second connection line WL2 may be arranged above the first connection line WL1, and may cover up to a side surface of the first connection line WL1.

According to an embodiment, the first connection line WL1 and the second connection line WL2 may have resistance variation rates according to different elongation rates. In more detail, compared to the second connection line WL2, the first connection line WL1 may include a suitable material having a less initial resistance in an undeformed state and a higher resistance variation rate according to an elongation rate. Compared to the first connection line WL1, the second connection line WL2 may include a suitable material having a greater initial resistance in an undeformed state and a lower resistance variation rate according to an elongation rate.

In this case, the first connection line WL1 may perform a main line role in the undeformed state, and thus, a part of the connection line WL directly in contact with the first line L1 and the second line L2 may be the first connection line WL1. In other words, as illustrated in FIG. 13, the first line L1 and the second line L2 may be directly in contact with a lower surface of the first connection line WL1.

However, when the display panel 10 is in a high deformation state, the main line role may be performed by the second connection line WL2. Thus, an electrical signal may be transmitted from the first connection line WL1 to the second connection line WL2, and thus, a contact area between the first connection line WL1 and the second connection line WL2 may be maximized or increased.

Thus, the second connection line WL2 may cover at least some of side surfaces of the first connection line WL1. For example, when the second connection line WL2 is arranged on the first connection line WL1 as illustrated in FIG. 13, the second connection line WL2 may cover the remaining side surfaces except for the lower surface of the first connection line WL1. In other words, the second connection line WL2 may cover an upper surface and four side surfaces of the first connection line WL1. This may not only increase the contact area between the first connection line WL1 and the second connection line WL2, but may also improve the flexibility of the display panel 10, because the second connection line WL2 may have a higher flexibility than that of the first connection line WL1.

Also, according to an embodiment, an interface in contact with the second connection line WL2 from among the side surfaces of the first connection line WL1 may include a plurality of protrusions toward the second connection line WL2. In more detail, the plurality of protrusions of the first connection line WL1 may protrude in a direction from the first connection line WL1 toward the second connection line WL2, and may have a suitable shape of being stuck in the second connection line WL2. The plurality of protrusions (e.g., tips thereof) of the first connection line WL1 may be arranged to be spaced apart from each other by a uniform or substantially uniform distance.

In the display panel 10 according to an embodiment of the present disclosure, the connection line WL may include the structure in which the first connection line WL1 and the second connection line WL2 are stacked, and thus, the resistance variation of the connection line WL according to the elongation rate may be reduced and the flexibility thereof may be increased. Also, the display panel 10 according to an embodiment of the present disclosure may have the characteristics for increasing the contact area between the first connection line WL1 and the second connection line WL2, and thus, the resistance variation rate according to a deformation of the connection line WL may be efficiently reduced, and excellent electrical characteristics may be maintained.

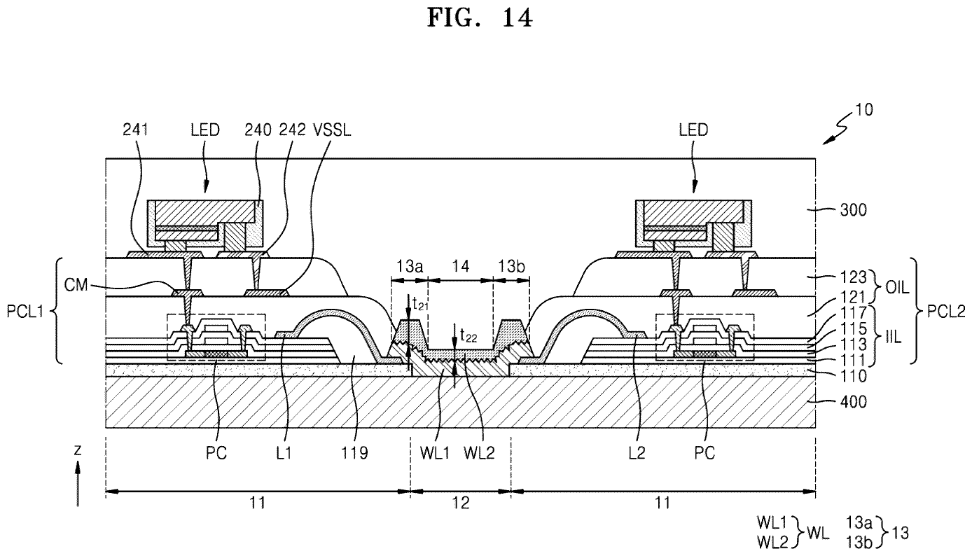

FIG. 14 is a schematic cross-sectional view of a portion of a display panel according to an embodiment of the present disclosure.

Referring to FIG. 14, except for the characteristics about the connection line WL, other characteristics are the same or substantially the same as described above with reference to FIGS. 12 and 13. In FIG. 14, the same or substantially the same elements as those described above with reference to FIGS. 12 and 13 are indicated by the same reference numerals, and thus, redundant description thereof may not be repeated and the differences may be mainly described in more detail hereinafter.

Referring to FIG. 14, the connection line WL may include a structure in which the first connection line WL1 and the second connection line WL2 having resistance variation rates according to different elongation rates are stacked. In more detail, compared to the second connection line WL2, the first connection line WL1 may include a suitable material having a less initial resistance in an undeformed state and a higher resistance variation rate according to an elongation rate. Compared to the first connection line WL1, the second connection line WL2 may include a suitable material having a greater initial resistance in an undeformed state and a lower resistance variation rate according to an elongation rate.

According to an embodiment, areas of the second connection line WL2 may have a different thickness from each other. For example, the connection line WL may include a first edge portion 13a adjacent to the first pixel circuit layer PCL1, a second edge portion 13b adjacent to the second pixel circuit layer PCL2, and a central portion 14 arranged between the first edge portion 13a and the second edge portion 13b. An edge portion 13 of the connection line WL including the first edge portion 13a and the second edge portion 13b may denote an end area of the connection line WL. The edge portion 13 of the connection line WL may be arranged on a boundary between the first area 11 and the second area 12. In other words, the edge portion 13 of the connection line WL may be an area where a strain may be relatively more concentrated, compared to the central portion 14 of the connection line WL.

Thus, according to an embodiment, a thickness t₂₁ of the edge portion 13 of the second connection line WL2 may be greater than a thickness t₂₂ of the central portion 14 of the second connection line WL2. In other words, each of the thickness t₂₁ of the first edge portion 13a of the second connection line WL2 and the thickness of the second edge portion 13a of the second connection line WL2 may be greater than the thickness t₂₂ of the central portion 14 of the second connection line WL2.

In more detail, the thickness of the first connection line WL1 and the thickness of the second connection line WL2 may satisfy the following Equation 1.

$$R = \frac{1}{\frac{1}{{R}_{1}} + \frac{1}{{R}_{2}}} = \frac{\frac{L}{w}}{\frac{{t}_{1}}{{ρ}_{1}} + \frac{{t}_{2}}{{ρ}_{2}}} \qquad Equation 1$$

In Equation 1, R is a resistance of the connection line WL, R₁ is a resistance of the first connection line WL1, R₂ is a resistance of the second connection line WL2, L is a length of the connection line WL, w is a width of the connection line WL, t₁ is a thickness of the first connection line WL1, ρ₁ is a specific resistance of the first connection line WL1, t₂ is a thickness of the second connection line WL2, and ρ₂ is a specific resistance of the second connection line WL2.

As described above, in an undeformed state or a low deformation state, the first connection line WL1 may perform a main line role, and in a high deformation state, the second connection line WL2 may perform a main line role. In more detail, the edge portion 13 of the connection line WL may be an area where a strain may be concentrated in the high deformation state, and thus, the thickness t₂₁ of the edge portion 13 of the second connection line WL2 may be greater than the thickness t₂₂ of the central portion 14 of the second connection line WL2. In addition, for the second connection line WL2 to affect the resistance of the connection line WL in the high deformation state, the edge portion 13 of the connection line WL may satisfy the following Equation 2 and Equation 3.

$$\frac{{t}_{1}}{{ρ}_{1}} \leq \frac{{t}_{21}}{{ρ}_{2}} \qquad Equation 2$$

$$\frac{{ρ}_{2}}{{ρ}_{1}} {t}_{1} \leq {t}_{21} \leq 3 {t}_{1} \qquad Equation 3$$

In Equation 2 and Equation 3, t₁ is a thickness of the first connection line WL1, ρ₁ is a specific resistance of the first connection line WL1, t₂₁ is a thickness of the edge portion 13 of the second connection line WL2, and ρ₂ is a specific resistance of the second connection line WL2.

On the other hand, the central portion 14 of the connection line WL, where the strain may be relatively less concentrated than the edge portion 13, may satisfy the following Equation 4.

$$0 < {t}_{22} < \frac{{ρ}_{2}}{{ρ}_{1}} {t}_{1} \qquad Equation 4$$

In Equation 4, t₁ is a thickness of the first connection line WL1, ρ₁ is a specific resistance of the first connection line WL1, t₂₂ is a thickness of the central portion 14 of the second connection line WL2, and ρ₂ is a specific resistance of the second connection line WL2.

As described above, the thickness t₂₁ of the edge portion 13 of the second connection line WL2 may be greater than the thickness t₂₂ of the central portion 14 of the second connection line WL2, and thus, in the high deformation state of the display panel 10, a resistance bottleneck phenomenon that may occur at the edge portion 13 of the second connection line WL2 may be alleviated. In other words, the display panel 10 according to an embodiment of the present disclosure may stably maintain the resistance of the connection line WL not only in the undeformed state, but also in the high deformation state.

The thickness of each of the first connection line WL1 and the second connection line WL2 may also vary according to a resolution of the display panel 10. In more detail, the resolution of the display panel 10 increasing may denote that a greater number of pixels P (e.g., see FIG. 4) may be arranged in a unit area of the display panel 10. In other words, to increase the resolution of the display panel 10, a greater number of pixels P (e.g., see FIG. 4) may be arranged, and thus, the size of the first area 11 (e.g., see FIG. 12) may be reduced. The width and the length of the connection line WL may be adjusted according to sizes of the first area 11 (e.g., see FIG. 12) and the unit area, and according to the width and the length of the connection line WL, thicknesses of the first connection line WL1 and the second connection line WL2 may be determined (e.g., may be set).

As described above, the thickness of the connection line WL may be variously adjusted according to the resolution of the display panel 10, and in more detail, in the second connection line WL2, the thicknesses of the edge portion 13 and the central portion 14 may be determined (e.g., may be set) to be different from each other. Thus, the display panel 10 according to an embodiment of the present disclosure may stably maintain the electrical characteristic in a high deformation state, even while the display 10 has a high resolution.

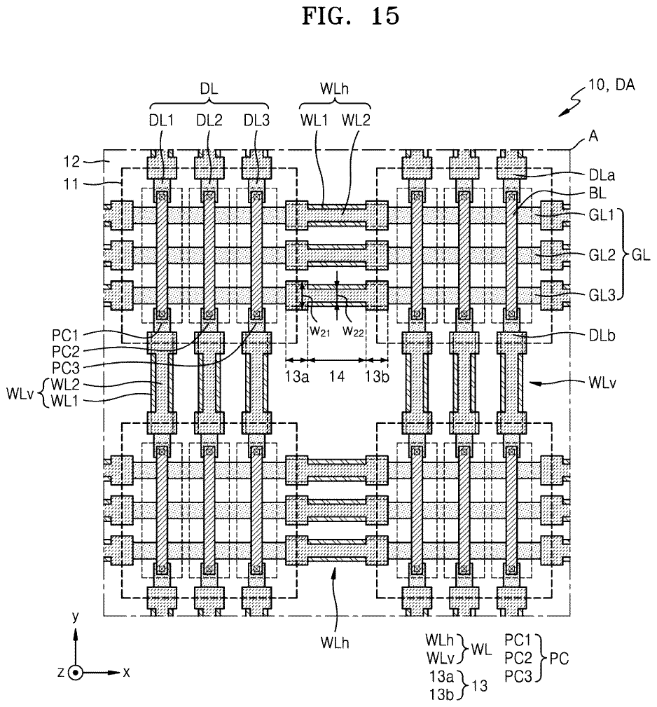

FIG. 15 is a schematic plan view of a portion of a display panel according to an embodiment of the present disclosure.

Referring to FIG. 15, except for the characteristics about the connection line WL, other characteristics are the same as those described above with reference to FIGS. 12 and 13. In FIG. 15, the same or substantially the same elements as those described above with reference to FIGS. 12 and 13 are indicated by the same reference numerals, and thus, redundant description thereof may not be repeated and the differences may be mainly described in more detail hereinafter.

Referring to FIG. 15, the connection line WL may include a structure in which the first connection line WL1 and the second connection line WL2 having resistance variation rates according to different elongation rates are stacked. In more detail, compared to the second connection line WL2, the first connection line WL1 may include a suitable material having a less initial resistance in an undeformed state and a higher resistance variation rate according to an elongation rate. Compared to the first connection line WL1, the second connection line WL2 may include a suitable material having a greater initial resistance in an undeformed state and a lower resistance variation rate according to an elongation rate. In an undeformed state or a low deformation state, the first connection line WL1 may perform a main line role, and in a high deformation state, the second connection line WL2 may perform a main line role.

According to an embodiment, areas of the second connection line WL2 may have a different width from each other. For example, the connection line WL may include the first edge portion 13a adjacent to the first pixel circuit layer PCL1, the second edge portion 13b adjacent to the second pixel circuit layer PCL2, and the central portion 14 arranged between the first edge portion 13a and the second edge portion 13b. The edge portion 13 of the connection line WL including the first edge portion 13a and the second edge portion 13b may denote an end area of the connection line WL. The edge portion 13 of the connection line WL may be arranged on a boundary between the first area 11 and the second area 12. In other words, the edge portion 13 of the connection line WL may be an area where a strain may be relatively more concentrated, compared to the central portion 14 of the connection line WL.

Thus, according to an embodiment, a width w₂₁ of the edge portion 13 of the second connection line WL2 may be greater than a width w₂₂ of the central portion 14 of the second connection line WL2. In other words, each of the width w₂₁ of the first edge portion 13a of the second connection line WL2 and the width of the second edge portion 13b of the second connection line WL2 may be greater than the width w₂₂ of the central portion 14 of the second connection line WL2.

In more detail, the edge portion 13 of the connection line WL may satisfy the following Equation 5.

$${w}_{1} \leq {w}_{21} \leq {w}_{1} + 20 μm \qquad Equation 5$$

In Equation 5, w₁ is a width of the first connection line wL1, and w₂₁ is a width of the edge portion 13 of the second connection line WL2.

On the other hand, the central portion 14 of the connection line WL may satisfy the following Equation 6.

$$0 \leq {w}_{22} \leq {w}_{1} - 30 μm \qquad Equation 6$$

In Equation 6, w₁ is a width of the first connection line wL1, and w₂₂ is a width of the central portion 14 of the second connection line WL2.

As described above, the width w₂₁ of the edge portion 13 of the second connection line WL2 may be greater than the width w₂₂ of the central portion 14 of the second connection line wL2, and thus, in the high deformation state of the display panel 10, a resistance bottleneck phenomenon that may occur at the edge portion of the second connection line WL2 may be alleviated. In other words, the display panel 10 according to an embodiment of the present disclosure may stably maintain the resistance of the connection line WL not only in the undeformed state, but also in the high deformation state.

The width of each of the first connection line WL1 and the second connection line WL2 may also vary according to the resolution of the display panel 10. In more detail, the resolution of the display panel 10 increasing may denote that a greater number of pixels P (e.g., see FIG. 4) may be arranged in a unit area of the display panel 10. In other words, to increase the resolution of the display panel 10, a greater number of pixels P (e.g., see FIG. 4) may be arranged, and thus, the size of the first area 11 (e.g., see FIG. 12) may be reduced. The width and the length of the first connection line WL may be variously adjusted according to sizes of the first area 11 (e.g., see FIG. 12) and the unit area, and according to the width and the length of the first connection line WL, a width of the second connection line WL2 may be determined (e.g., may be set).

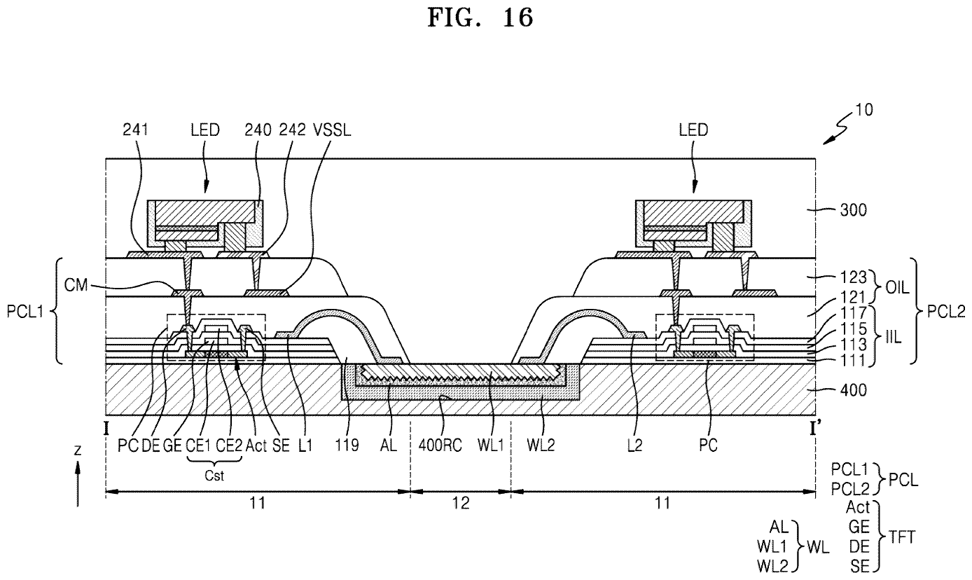

FIG. 16 is a schematic cross-sectional view of a portion of a display panel according to an embodiment of the present disclosure.

Referring to FIG. 16, except for the characteristics about the connection line WL, other characteristics are the same as those described above with reference to FIGS. 9 to 11. In FIG. 16, the same or substantially the same elements as those described above with reference to FIGS. 9 to 11 are indicated by the same reference numerals, and thus, redundant description thereof may not be repeated and the differences may be mainly described in more detail hereinafter.

Referring to FIG. 16, the connection line WL may include a suitable structure in which the first connection line WL1 and the second connection line WL2 are stacked. The first connection line WL1 may include a suitable material having a low initial resistance in an undeformed state and a high resistance variation rate according to an elongation rate, and the second connection line WL2 may include a suitable material having a high initial resistance in an undeformed state and a low resistance variation rate according to an elongation rate.

According to an embodiment, the connection line WL may further include an adhesion layer AL arranged between the first connection line WL1 and the second connection line WL2. As described above, in the undeformed state, the first connection line WL1 may perform a main line role, and in the high deformation state, the second connection line WL2 may perform the main line role, and thus, a line switching between the first connection line WL1 and the second connection line WL2 may be smoothly performed when a degree of adhesion between the first connection line WL1 and the second connection line WL2 is high. Thus, the adhesion layer AL may be added to the connection line WL to increase the adhesion between the first connection line WL1 and the second connection line WL2.

According to an embodiment, the adhesion layer AL may include a metal nano particle and a liquid metal particle, may have the same material base (e.g., matrix) as those of the first connection line WL1 and the second connection line WL2, and may include a curable elastomer. For example, the adhesion layer AL may include an Ag nanoparticle/epoxy-terminated PDMS composite.

Some of side surfaces of the first connection line WL1 may include a plurality of protrusions toward the second connection line WL2. As illustrated in FIG. 16, when the adhesion layer AL is arranged between the first connection line WL1 and the second connection line WL2, the plurality of protrusions of the first connection line WL1 may protrude in a direction from the first connection line WL1 toward the adhesion layer AL, and may have a suitable shape that is stuck in the adhesion layer AL.

As described above, in the display panel 10 according to an embodiment of the present disclosure, the adhesion layer AL may be arranged between the first connection line WL1 and the second connection line WL2 having the resistance variation rates according to the different elongation rates, and thus, the adhesion between the first connection line WL1 and the second connection line WL2 may be increased, and the resistance variation of the connection line WL may be effectively reduced.

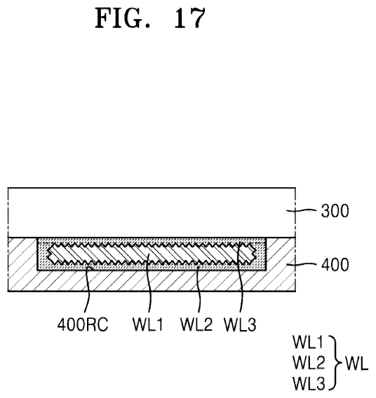

FIG. 17 is a schematic cross-sectional view of a portion of a display panel according to an embodiment of the present disclosure.

Referring to FIG. 17, except for the characteristics about the connection line WL, other characteristics are the same as those described above with reference to FIGS. 9 to 11. In FIG. 17, the same or substantially the same elements as those described above with reference to FIGS. 9 to 11 are indicated by the same reference numerals, and thus, redundant description thereof may not be repeated and the differences may be mainly described in more detail hereinafter.

Referring to FIG. 17, the connection line WL may include a suitable structure in which the first connection line WL1 and the second connection line WL2 are stacked. The first connection line WL1 may include a suitable material having a low initial resistance in an undeformed state and a high resistance variation rate according to an elongation rate, and the second connection line WL2 may include suitable a material having a high initial resistance in an undeformed state and a low resistance variation rate according to an elongation rate.

According to an embodiment, the connection line WL may further include a third connection line WL3 arranged on the first connection line WL1 and the second connection line WL2. In more detail, as illustrated in FIG. 17, the second connection line WL2 may cover a lower surface and side surfaces of the first connection line WL1, and the third connection line WL3 may cover an upper surface of the first connection line WL1. In other words, the second connection line WL2 and the third connection line WL3 may surround (e.g., around a periphery of) the first connection line WL1.

According to an embodiment, the third connection line WL3 may include the same material as that of the second connection line WL2. In other words, like the second connection line WL2, the third connection line WL3 may include a suitable material having a high initial resistance in an undeformed state and a low resistance variation rate according to an elongation rate. For example, the third connection line WL3 may include an Ag nanowire.

The third connection line WL3 and the second connection line WL2 include the same material as each other, and thus, the connection line WL may have a suitable shape as if the second connection line WL2 surrounds (e.g., around a periphery of) the first connection line WL1. The second connection line WL2 and the third connection line WL3 surround (e.g., around a periphery of) the first connection line WL1, and thus, an area in which the first connection line WL1 is in contact with the second connection line WL2 or the third connection line WL3 may further increase. Thus, in the display panel 10 according to an embodiment of the present disclosure, a main line role may be efficiently switched between the first connection line WL1 and the second connection line WL2 (e.g., and/or the third connection line), and the resistance variation rate according to deformation of the connection line WL may be reduced. In addition, the second connection line WL2 (e.g., and/or the third connection line) may have a higher flexibility than the first connection line WL1, and thus, the flexibility of the display panel 10 may be improved.

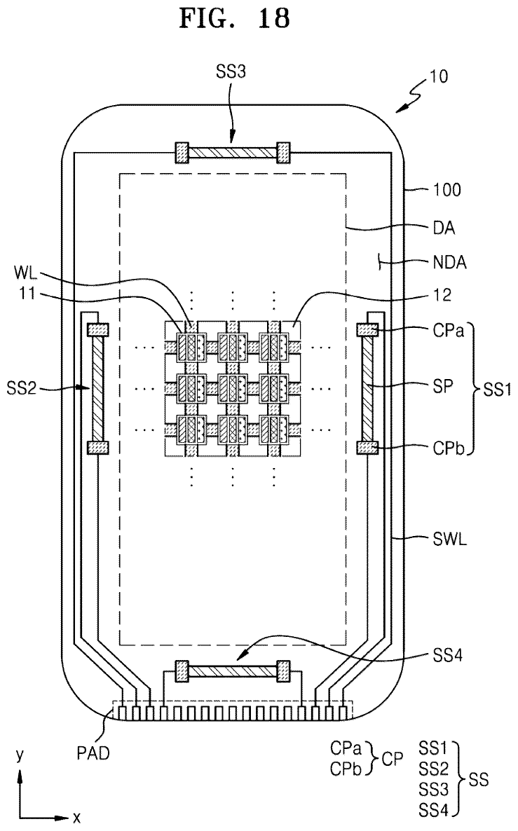

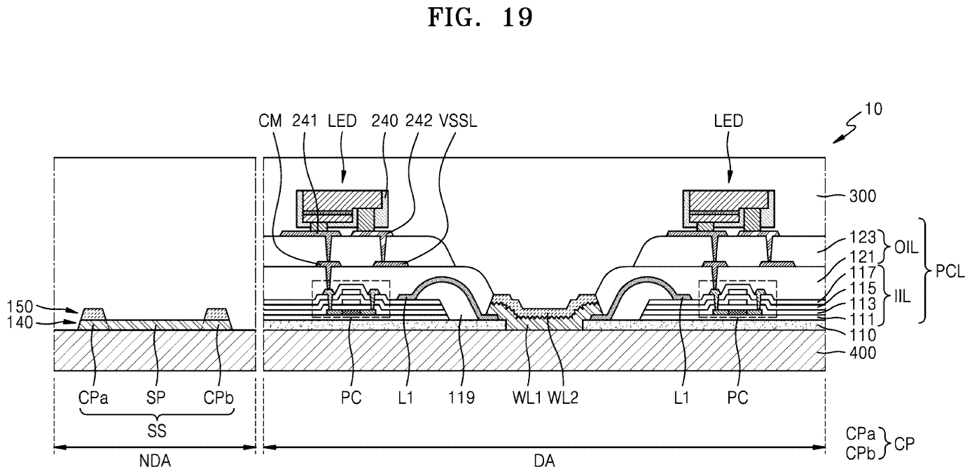

FIG. 18 is a schematic plan view of a display panel according to an embodiment of the present disclosure. FIG. 19 is a schematic cross-sectional view of a portion of a display panel according to an embodiment of the present disclosure.

Referring to FIGS. 18 and 19, except for a strain sensor SS, other characteristics are the same as those described above with reference to FIGS. 9 to 11. In FIGS. 18 and 19, the same or substantially the same elements as those described above with reference to FIGS. 9 to 11 are indicated by the same reference numerals, and thus, redundant description thereof may not be repeated and the differences may be mainly described in more detail hereinafter.

Referring to FIG. 18, the display panel 10 may include the display area DA and the non-display area NDA surrounding (e.g., around a periphery of) the display area DA. The display area DA may include the plurality of first areas 11 in which the pixels are arranged, and the second area 12 surrounding (e.g., around a periphery of) each of the plurality of first areas 11. The connection line WL for electrically connecting the pixel circuit arranged in each of two adjacent first areas 11 may be arranged in the second area 12.

According to an embodiment, the strain sensors SS may be arranged in the non-display area NDA. The strain sensor SS may have a resistance that varies according to whether or not the display panel 10 is deformed and the degree of deformation. The strain sensor SS may be arranged at an outer portion of the display panel 10, and may have the resistance that varies according to a deformation of the shape of the display panel 10. The strain sensor SS may provide information about whether or not the display panel is deformed and the degree of deformation through the resistance variation.

The strain sensors SS may be arranged in the non-display area NDA at the outer portion of the display panel 10. For example, as illustrated in FIG. 18, the strain sensor SS may include a first strain sensor SS1 arranged at a right side outer portion of the display area DA, a second strain sensor SS2 arranged at a left side outer portion of the display area DA, a third strain sensor SS3 arranged at an upper side outer portion of the display area DA, and a fourth strain sensor SS4 arranged at a lower side outer portion of the display area DA. By assembling information provided from the first to fourth strain sensors SS1, SS2, SS3, and SS4, a determination may be made as to whether or not the display panel 10 is deformed and the degree of deformation.

A plurality of pads PAD may be arranged in the non-display area NDA. The plurality of pads PAD may be arranged along a first direction (e.g., the x direction) to be spaced apart from each other. The plurality of pads PAD may include a pixel pad electrically connected to the pixel, and a sensing pad electrically connected to the strain sensor SS. Also, in the non-display area NDA, a circuit substrate may be arranged and connected to the plurality of pixels arranged in the display area DA and the plurality of strain sensors SS arranged in the non-display area NDA.

According to an embodiment, a sensor line SWL for electrically connecting the strain sensor SS with the sensing pad may be arranged in the non-display area NDA. The sensor line SWL may connect the plurality of strain sensors SS to some of the plurality of pads PAD, respectively.

Referring to FIGS. 18 and 19, the strain sensor SS may include a sensing portion SP, and a connection portion CP connecting the sensing portion SP with the sensor line SWL. The connection portion CP may include a first connection portion CPa and a second connection portion CPb arranged at both sides (e.g., opposite sides) of the sensing portion SP. The strain sensor SS may sense whether or not the display panel 10 is deformed and the degree of deformation, through a resistance variation according to a physical deformation of the sensing portion SP. The connection portion CP may transmit the resistance variation sensed by the sensing portion SP to the sensor line SWL.

According to an embodiment, the sensing portion SP may include a first layer 140 including the same material as that of the first connection line WL1. In other words, the sensing portion SP may be arranged on the same or substantially the same layer as that of the first connection line WL1 of the display area DA, and may include the same material as that of the first connection line WL1. In other words, the sensing portion SP may include a suitable material having a low initial resistance in an undeformed state and a high resistance variation rate according to an elongation rate. For example, the sensing portion SP may include an Ag flake-PDMS composite. The sensing portion SP may include the same material as that of the first connection line WL1, or in other words, the material having the high resistance variation rate according to the elongation rate, and thus, may easily sense the degree of deformation of the display panel 10 by using the high resistance variation rate.

According to an embodiment, the connection portion CP and the sensor line SWL may include a structure in which the first layer 140 and a second layer 150 are stacked, the first layer 140 including the same material as that of the first connection line WL1, and the second layer 150 including the same material as that of the second connection line WL2. In other words, each of the connection portion CP and the sensor line SWL may be arranged on the same or substantially the same layer as that of the connection line WL, in which the first connection line WL1 and the second connection line WL2 are stacked, and may include the same material as that of the connection line WL. In other words, compared to the first layer 140, the second layer 150 may include a suitable material having a greater initial resistance in an undeformed state and a higher resistance variation rate according to an elongation rate. For example, the second layer 150 may include an Ag nanowire.

The connection portion CP and the sensor line SWL may include the structure in which the first layer 140 and the second layer 150 having different resistance variations from each other are stacked, and thus, in the undeformed state of the display panel 10, the first layer 140 may perform a main line role, and in a high deformation state of the display panel 10, the second layer 150 may perform a main line role. In other words, the connection portion CP and the sensor line SWL may include the structure in which the first layer 140 and the second layer 150 are stacked, and thus, despite a deformation of the display panel 10, a resistance may be stably maintained.

As described above, according to the display panel 10 according to an embodiment of the present disclosure, the degree of deformation of the display panel 10 may be easily sensed through the sensing portion SP using the first layer 140 having a high resistance variation rate according to an elongation rate, and the flexibility may be improved and excellent electrical characteristics may be maintained through the connection portion CP and the sensor line SWL including the structure in which the first layer 140 and the second layer 150 are stacked.

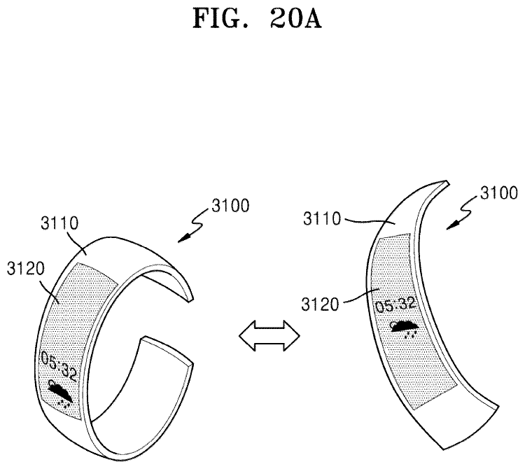

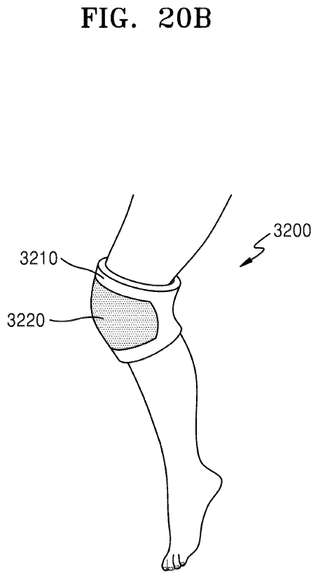

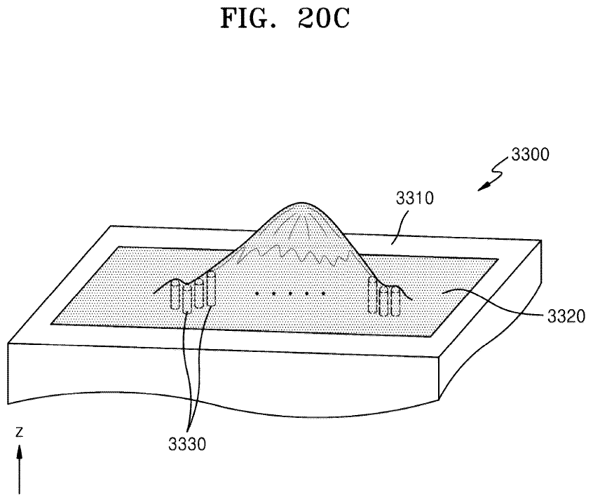

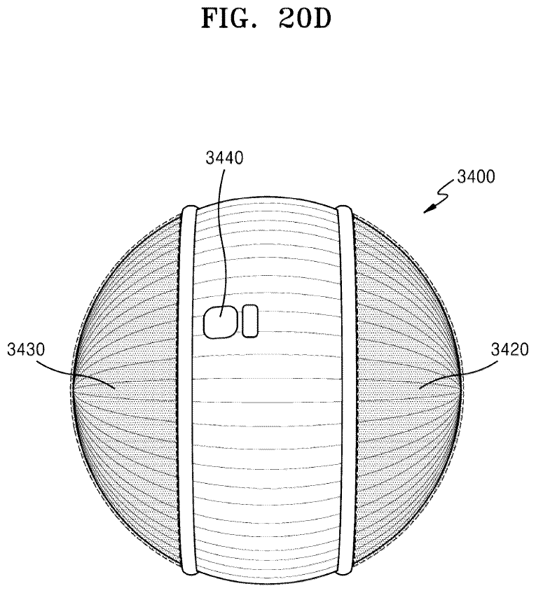

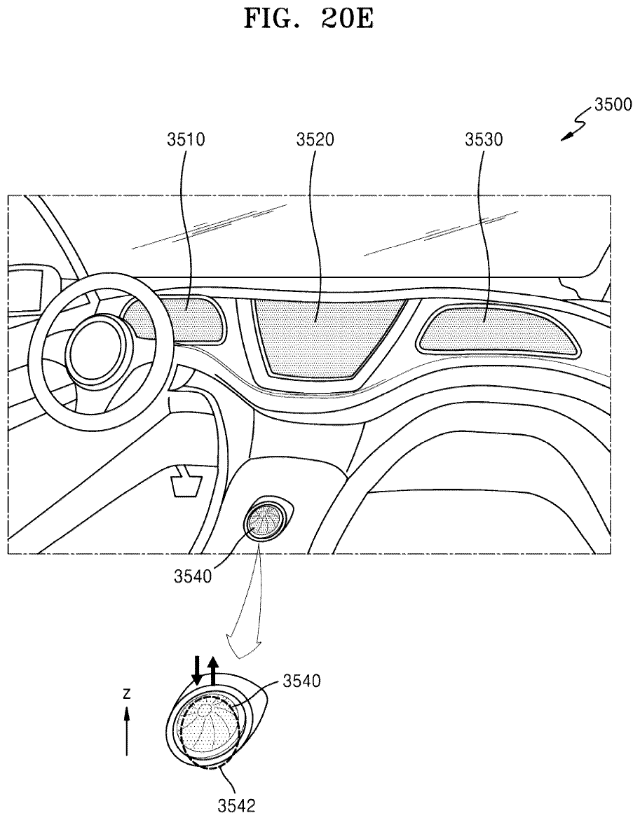

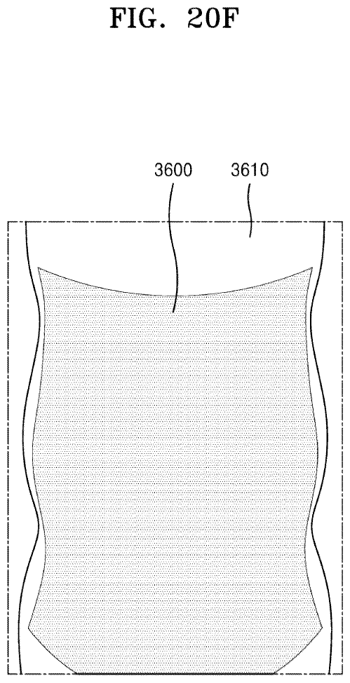

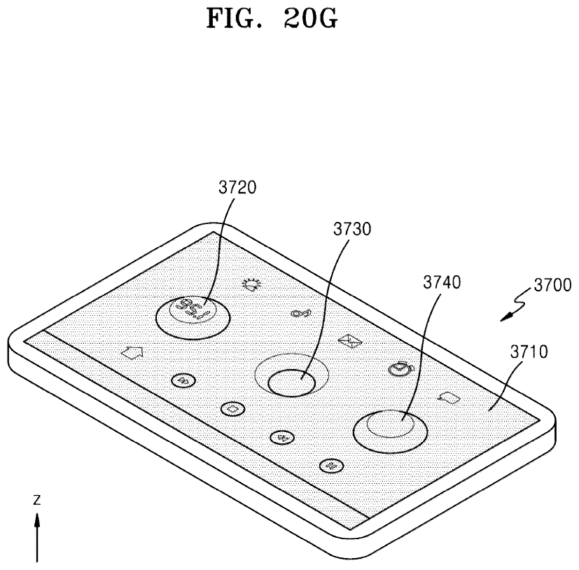

FIGS. 20A through 20G are schematic perspective views of some examples of an electronic device including a display panel according to some embodiments of the present disclosure.

Referring to FIG. 20A, the display panel according to an embodiment of the present disclosure may be used for a wearable electronic device 3100, which may be worn on a part of a user's human body. The wearable electronic device 3100 may include a body 3110, and a display 3120 provided in the body 3110. The display panel according to some embodiments of the present disclosure may be used as the display 3120 of the wearable electronic device 3100. The wearable electronic device 3100 may be deformed, as illustrated in FIG. 20A. According to an embodiment, according to selection of a user, the wearable electronic device 3100 may be used as a smart watch or a smartphone.

FIG. 20B illustrates a medical electronic device 3200. According to an embodiment, the medical electronic device 3200 may include a body 3210 and an emission portion 3220. The display panel according to some embodiments of the present disclosure may be used as the emission portion 3220 of the medical electronic device 3200. The emission portion 3220 may emit light of a desired wavelength band (e.g., a certain or predetermined wavelength band) (e.g., infrared rays, visible rays, and/or the like) to a human body of a patient. According to an embodiment, the body 3210 may include a flexible fiber material and may have a suitable structure that is wearable on a human body of a user of the emission portion.

FIG. 20C illustrates an educational electronic device 3300. According to an embodiment, the educational electronic device 3300 may include a display 3320 provided in a frame 3310. The display 3320 may use or include the display panel according to some embodiments of the present disclosure. An image, such as the sea swelling with waves, mountains covered with snow, volcanoes with flowing flames, or the like, may be provided through the display 3320, and in this case, the display 3320 may be stretched in a height direction (e.g., the z direction) by reflecting the height of the waves, mountains, or volcanoes. According to some embodiments, a portion of the display 3320 may have a height that is sequentially variable along a direction in which the flames flow, thereby three-dimensionally showing the movement of the flames. The educational electronic device 3300 may include a plurality of pins (e.g., strokes) 3330 arranged at a rear surface of the display 3320, so that the display 3320 may be stretched in a height direction. As the pins 3330 move in a third direction (e.g., the z direction or the −z direction), an image represented by the display 3320 may be realized to have a three-dimensional height. FIG. 20C illustrates the educational electronic device 3300. However, the present disclosure is not limited thereto, and the usage of the electronic device 3300 may be applied to all suitable devices providing image information (e.g., certain or predetermined image information).

The electronic devices illustrated in FIGS. 20A to 20C may have various variable shapes. However, the present disclosure is not limited thereto. As described according to some embodiments below, the display panel may be used for an electronic device having a fixed portion (e.g., a screen) configured to display an image.

FIG. 20D illustrates a robot 3400 as another electronic device according to an embodiment of the present disclosure. The robot 3400 may recognize a movement or an object by using a camera 3440, and may display an image (e.g., a certain or predetermined image) for a user through displays 3420 and 3430. According to some embodiments, the display panels according to an embodiment of the present disclosure may be stretched in various directions as described above, and thus, may be assembled into a body frame having a semicircular shape. Thus, the robot 3400 may include the displays 3420 and 3430 having semicircular shapes.

FIG. 20E illustrates a vehicle display device 3500 as an electronic device according to an embodiment of the present disclosure. The vehicle display device 3500 may include a cluster 3510, a CID 3520, and/or a co-driver display 3530. The display panel according to an embodiment of the present disclosure may be stretched in various suitable directions, and thus, may not be restricted by the shape of an internal frame of a vehicle, and may be used for the cluster 3510, the CID 3520, and/or the co-driver display 3530.

FIG. 20E illustrates that the cluster 3510, the CID 3520, and/or the co-driver display 3530 are separate devices from each other. However, the present disclosure is not limited thereto. According to another embodiment, two or more selected from among the cluster 3510, the CID 3520, and/or the co-driver display 3530 may be integrally connected to each other.

According to some embodiments, the vehicle display device 3500 may include a button 3540 configured to display an image (e.g., a certain or predetermined image). With reference to an enlarged view in FIG. 20E, the button 3540 having a semicircular shape may include an object 3542 for providing a sense of use of a button by moving in the z direction or the −z direction, and a display apparatus disposed above the object 3542. According to some embodiments, when the object 3542 has a three-dimensionally round surface, the display apparatus may also have a three-dimensionally round surface.

FIG. 20F illustrates that the electronic device according to an embodiment of the present disclosure may correspond to an electronic device 3600 for an advertisement or an exhibition. According to some embodiments, the electronic device 3600 for the advertisement or the exhibition may be mounted on a structure 3610 that is fixed, such as a wall or a pillar. When the structure 3610 includes a concavo-convex surface as illustrated in FIG. 20F, the electronic device 3600 for the advertisement or the exhibition may also be arranged along the concavo-convex surface of the structure 3610. According to some embodiments, the electronic device 3600 for the advertisement or the exhibition may be mounted on the structure 3610 by using a thermal contraction film and/or the like

FIG. 20G illustrates that the electronic device according to an embodiment of the present disclosure corresponds to a controller 3700. The controller 3700 may include an image-kind of button. For example, the controller 3700 may include first to third button areas 3720, 3730, and 3740, in which portions of a display 3710, protrude in the z direction or protrude in the −z direction (e.g., are recessed from the z direction). According to some embodiments, the first and third button areas 3720 and 3740 may protrude in the z direction, and the second button area 3730 may protrude in the −z direction (e.g., may be recessed from the z direction).

An embodiment of the present disclosure provides a display panel including: a base layer including a display area and a non-display area surrounding the display area; a first pixel circuit layer arranged in the display area of the base layer and including a transistor and insulating layers; a second pixel circuit layer arranged in the display area of the base layer and including a transistor and insulating layers; a first light-emitting diode arranged on the first pixel circuit layer and electrically connected to the transistor of the first pixel circuit layer; a second light-emitting diode arranged on the second pixel circuit layer and electrically connected to the transistor of the second pixel circuit layer; and a connection line for electrically connecting the transistor of the first pixel circuit layer to the transistor of the second pixel circuit layer, wherein the connection line includes a structure in which a first connection line and a second connection line are stacked, the second connection having a lower resistance variation rate according to an elongation rate than the first connection line.

According to an embodiment, an initial resistance of the second connection line in an undeformed state may be greater than an initial resistance of the first connection line in the undeformed state.

According to an embodiment, the display panel may further include a first line electrically connected to the transistor of the first pixel circuit layer; and a second line electrically connected to the transistor of the second pixel circuit layer, wherein the connection line electrically may connect the first line to the second line, and the first connection line may be in direct contact with the first line and the second line.

According to an embodiment, the second connection line may cover at least some of side surfaces of the first connection line.

According to an embodiment, an interface from among side surfaces of the first connection line, the interface being in contact with the second connection line, may include a plurality of protrusions toward the second connection line.

According to an embodiment, the base layer may include a recess portion on an upper surface toward the first pixel circuit layer and the second pixel circuit layer, the connection line may be arranged in the recess portion, and the first connection line may be arranged on the second connection line.

According to an embodiment, the second connection line may cover a lower surface and side surfaces of the first connection line, and the second connection line may be in contact with the base layer.

According to an embodiment, the connection line may be arranged on an upper surface of the base layer toward the first pixel circuit layer and the second pixel circuit layer, and the second connection line may be arranged on the first connection line.

According to an embodiment, the display panel may further include a protective layer covering the first light-emitting diode and the second light-emitting diode, wherein the second connection line may be in contact with the protective layer.

According to an embodiment, the connection line may include: a first edge portion adjacent to the first pixel circuit layer; a second edge portion adjacent to the second pixel circuit layer; and a central portion arranged between the first edge portion and the second edge portion.

According to an embodiment, based on a thickness direction of the base layer, each of a thickness of the first edge portion of the second connection line and a thickness of the second edge portion of the second connection line may be greater than a thickness of the central portion of the second connection line.

According to an embodiment, based on the thickness direction of the base layer, each of the thickness of the first edge portion of the second connection line and the thickness of the second edge portion of the second connection line may satisfy

$$\frac{{ρ}_{2}}{{ρ}_{1}} {t}_{1} \leq {t}_{21} \leq 3 {t}_{1} ,$$

where t₂₁ is the thickness of the first edge portion (e.g., the second edge portion) of the second connection line, t₁ is a thickness of the first connection line, ρ₁ is a specific resistance of the first connection line, and ρ₂ is a specific resistance of the second connection line.

According to an embodiment, based on the thickness direction of the base layer, the thickness of the central portion of the second connection line may satisfy

$$0 < {t}_{22} < \frac{{ρ}_{2}}{{ρ}_{1}} {t}_{1} ,$$

where t₂₂ is the thickness of the central portion of the second connection line, t₁ is a thickness of the first connection line, ρ₁ is a specific resistance of the first connection line, and p₂ is a specific resistance of the second connection line.

According to an embodiment, when viewed in a direction perpendicular to the base layer, the first edge portion, the central portion, and the second edge portion may be sequentially arranged in a first direction, and based on a second direction crossing the first direction, each of a width of the first edge portion of the second connection line and a width of the second edge portion of the second connection line may be greater than a width of the central portion of the second connection line.

According to an embodiment, when viewed in the direction perpendicular to the base layer, each of the width of the first edge portion of the second connection line in the second direction and the width of the second edge portion of the second connection line in the second direction may satisfy w₁≤w₂₁≤w₁+20 μm, where w₁ is a width of the first connection line, and w₂₁ is the width of the first edge portion (e.g., the second edge portion) of the second connection line.

According to an embodiment, when viewed in the direction perpendicular to the base layer, the width of the central portion of the second connection line in the second direction may satisfy 0≤w₂₂≤w₁−30 μm, where w₁ is a width of the first connection line, and w₂₂ is the width of the central portion of the second connection line.

According to an embodiment, the connection line may further include an adhesion layer arranged between the first connection line and the second connection line.

According to an embodiment, an interface from among side surfaces of the first connection line, the interface being in contact with the adhesion layer, may include a plurality of protrusions toward the adhesion layer.

According to an embodiment, the connection line may further include a third connection line including a same material as the second connection line, and the second connection line may cover a lower surface and side surfaces of the first connection line, and the third connection line may cover an upper surface of the first connection line.

According to an embodiment, the second connection line and the third connection line may surround the first connection line.

According to an embodiment, the display panel may further include: a strain sensor arranged in the non-display area of the base layer; and a sensor line configured to transmit an electrical signal of the strain sensor, wherein the strain sensor may include a sensing portion and a connection portion for connecting the sensing portion to the sensor line.

According to an embodiment, the sensing portion may be arranged on a same layer as the first connection line and may include a same material as the first connection line.

According to an embodiment, each of the connection portion and the sensor line may include: a first layer arranged on a same layer as the first connection line and including a same material as the first connection line; and a second layer arranged on a same layer as the second connection line and including a same material as the second connection line.

Another embodiment of the present disclosure provides an electronic device including: a display panel; and a lower cover forming an exterior shape and having an opening in a front surface, the opening exposing a portion of the display panel, wherein the display panel includes: a base layer including a display area and a non-display area surrounding the display area; a first pixel circuit layer arranged in the display area of the base layer and including a transistor and insulating layers; a second pixel circuit layer arranged in the display area of the base layer and including a transistor and insulating layers; a first light-emitting diode arranged on the first pixel circuit layer and electrically connected to the transistor of the first pixel circuit layer; a second light-emitting diode arranged on the second pixel circuit layer and electrically connected to the transistor of the second pixel circuit layer; and a connection line for electrically connecting the transistor of the first pixel circuit layer to the transistor of the second pixel circuit layer, wherein the connection line includes a structure in which a first connection line and a second connection line are stacked, the second connection having a lower resistance variation rate according to an elongation rate than the first connection line.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

### DESCRIPTION OF SOME REFERENCE SYMBOLS

1: electronic device
10: display panel
DA: display area
NDA: non-display area
PC: pixel circuit
LED: light-emitting diode
11: first area
12: second area
WL: connection line
WL1: first connection line
WL2: second connection line
13: edge portion
14: central portion
AL: adhesion layer
WL3: third connection line
SS: strain sensor
SP: sensing portion
CP: connection portion
SWL: sensor line
140: first layer
150: second layer

What is claimed is:

1. A display panel comprising:
a base layer comprising a display area, and a non-display area surrounding around the display area;
a first pixel circuit layer in the display area of the base layer, and comprising a transistor and insulating layers;
a second pixel circuit layer in the display area of the base layer, and comprising a transistor and insulating layers;
a first light-emitting diode on the first pixel circuit layer, and electrically connected to the transistor of the first pixel circuit layer;
a second light-emitting diode on the second pixel circuit layer, and electrically connected to the transistor of the second pixel circuit layer; and
a connection line electrically connecting the transistor of the first pixel circuit layer to the transistor of the second pixel circuit layer,
wherein the connection line comprises a first connection line and a second connection line that are stacked, the second connection line having a lower resistance variation rate according to an elongation rate than that of the first connection line.

2. The display panel of claim 1, wherein an initial resistance of the second connection line in an undeformed state is greater than an initial resistance of the first connection line in the undeformed state.

3. The display panel of claim 1, further comprising:
a first line electrically connected to the transistor of the first pixel circuit layer; and
a second line electrically connected to the transistor of the second pixel circuit layer,
wherein the connection line electrically connects the first line to the second line, and
wherein the first connection line is in direct contact with the first line and the second line.

4. The display panel of claim 1, wherein the second connection line covers at least some of side surfaces of the first connection line.

5. The display panel of claim 1, wherein an interface in contact with the second connection line from among side surfaces of the first connection line comprises a plurality of protrusions protruding toward the second connection line.

6. The display panel of claim 1, wherein the base layer comprises a recess portion on an upper surface facing toward the first pixel circuit layer and the second pixel circuit layer,
wherein the connection line is located in the recess portion,
wherein the first connection line is on the second connection line,
wherein the second connection line covers a lower surface and side surfaces of the first connection line, and
wherein the second connection line is in contact with the base layer.

7. The display panel of claim 1, wherein the connection line is on an upper surface of the base layer facing toward the first pixel circuit layer and the second pixel circuit layer,
wherein the second connection line is on the first connection line,
wherein the display panel further comprises a protective layer covering the first light-emitting diode and the second light-emitting diode, and
wherein the second connection line is in contact with the protective layer.

8. The display panel of claim 1, wherein the connection line comprises:
a first edge portion adjacent to the first pixel circuit layer;
a second edge portion adjacent to the second pixel circuit layer; and
a central portion between the first edge portion and the second edge portion.

9. The display panel of claim 8, wherein, based on a thickness direction of the base layer, each of a thickness of the first edge portion of the second connection line and a thickness of the second edge portion of the second connection line is greater than a thickness of the central portion of the second connection line.

10. The display panel of claim 9, wherein, based on the thickness direction of the base layer, each of the thickness of the first edge portion of the second connection line and the thickness of the second edge portion of the second connection line satisfies
$$\frac{{ρ}_{2}}{{ρ}_{1}} {t}_{1} \leq {t}_{21} \leq 3 {t}_{1} ,$$
where t₂₁ is the thickness of the first edge portion or the second edge portion of the second connection line, t₁ is a thickness of the first connection line, ρ₁ is a specific resistance of the first connection line, and ρ₂ is a specific resistance of the second connection line.

11. The display panel of claim 9, wherein, based on the thickness direction of the base layer, the thickness of the central portion of the second connection line satisfies
$$0 < {t}_{22} < \frac{{ρ}_{2}}{{ρ}_{1}} {t}_{1} ,$$
where t₂₂ is the thickness of the central portion of the second connection line, t₁ is a thickness of the first connection line, ρ₁ is a specific resistance of the first connection line, and ρ₂ is a specific resistance of the second connection line.

12. The display panel of claim 8, wherein, in a plan view, the first edge portion, the central portion, and the second edge portion are sequentially located along a first direction, and
wherein based on a second direction crossing the first direction, each of a width of the first edge portion of the second connection line and a width of the second edge portion of the second connection line is greater than a width of the central portion of the second connection line.

13. The display panel of claim 12, wherein, in the plan view, each of the width of the first edge portion of the second connection line in the second direction and the width of the second edge portion of the second connection line in the second direction satisfies w₁≤w₂₁≤w₁+20 μm, where w₁ is a width of the first connection line, and w₂₁ is the width of the first edge portion or the second edge portion of the second connection line.

14. The display panel of claim 12, wherein, in the plan view, the width of the central portion of the second connection line in the second direction satisfies 0≤w₂₂≤w₁−30 μm, where w₁ is a width of the first connection line, and w₂₂ is the width of the central portion of the second connection line.

15. The display panel of claim 1, wherein the connection line further comprises an adhesion layer between the first connection line and the second connection line, and
wherein an interface in contact with the adhesion layer from among side surfaces of the first connection line comprises a plurality of protrusions protruding toward the adhesion layer.

16. The display panel of claim 1, wherein the connection line further comprises a third connection line comprising a same material as that of the second connection line,
wherein the second connection line covers a lower surface and side surfaces of the first connection line,
wherein the third connection line covers an upper surface of the first connection line, and
wherein the second connection line and the third connection line surround around the first connection line.

17. The display panel of claim 1, further comprising:
a strain sensor in the non-display area of the base layer; and
a sensor line configured to transmit an electrical signal of the strain sensor,
wherein the strain sensor comprises a sensing portion, and a connection portion connecting the sensing portion to the sensor line.

18. The display panel of claim 17, wherein the sensing portion is on a same layer as that of the first connection line, and comprises a same material as that of the first connection line.

19. The display panel of claim 17, wherein each of the connection portion and the sensor line comprises:
a first layer on a same layer as that of the first connection line, and comprising a same material as that of the first connection line; and
a second layer on a same layer as that of the second connection line, and comprising a same material as that of the second connection line.

20. An electronic device comprising:
a display panel; and
a lower cover defining an exterior shape and having an opening in a front surface thereof, the opening exposing a portion of the display panel,
wherein the display panel comprises:
a base layer comprising a display area, and a non-display area surrounding around the display area;
a first pixel circuit layer in the display area of the base layer, and comprising a transistor and insulating layers;
a second pixel circuit layer in the display area of the base layer, and comprising a transistor and insulating layers;
a first light-emitting diode on the first pixel circuit layer, and electrically connected to the transistor of the first pixel circuit layer;
a second light-emitting diode on the second pixel circuit layer, and electrically connected to the transistor of the second pixel circuit layer; and
a connection line electrically connecting the transistor of the first pixel circuit layer to the transistor of the second pixel circuit layer, and
wherein the connection line comprises a first connection line and a second connection line that are stacked, the second connection having a lower resistance variation rate according to an elongation rate than that of the first connection line.
